(19) United States
(12) Patent Application Publication
(10) Pub. No.: US 2026/0033101 A1
(43) Pub. Date: Jan. 29, 2026

(54) DISPLAY DEVICE

(71) Applicant: LG Display Co., Ltd., Seoul (KR)

(72) Inventor: Seunghyeon JU, Jeonju-si (KR)

(73) Assignee: LG Display Co., Ltd., Seoul (KR)

(21) Appl. No.: 19/081,589

(22) Filed: Mar. 17, 2025

(30) Foreign Application Priority Data
Jul. 24, 2024 (KR) 10-2024-0098211

(51) Int. Cl. H10H 29/855; H10H 29/37

(52) U.S. Cl. CPC H10H 29/855; H10H 29/37

(57) ABSTRACT

A display device includes a substrate including a plurality of pixels; a plurality of pixel driving circuits respectively disposed on the plurality of pixels of the substrate; a plurality of banks disposed on each of the pixel driving circuits; a plurality of light-emitting elements respectively disposed on the plurality of banks; solder patterns disposed on the plurality of banks, wherein at least some of the solder patterns are respectively bonded to the plurality of light-emitting elements; an optical layer disposed on the plurality of banks; an electrode disposed on the plurality of light-emitting elements and the optical layer, wherein the optical layer is disposed between the solder pattern and the electrode.

### CROSS-REFERENCE TO RELATED APPLICATION

This application claims priority from Korean Patent Application No. 10-2024-0098211 filed on Jul. 24, 2024, in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device.

### Description of the Related Art

Display devices are applied to various electronic devices such as TV, mobile phones, laptops, and tablets.

The display device includes an organic light-emitting display device (OLED) that emits light by itself, and a liquid crystal display device (LCD) that requires a separate light source.

Recently, a display device including a light-emitting diode (LED) has attracted attention as a next-generation display device. Since the light-emitting diode is made of an inorganic material rather than an organic material, the display device including the light-emitting diode may have a faster lighting speed than that of the liquid crystal display device or the organic light-emitting display device, and may have excellent luminous efficiency, and may display an image with high luminance.

### BRIEF SUMMARY

Various embodiments of the present disclosure provide a display device capable of preventing an electrical short circuit from occurring between a first electrode and a second electrode by disposing a first optical layer having a sufficient thickness between a solder pattern and the second electrode.

Various embodiments of the present disclosure provide a display device in which a first optical layer of a multilayer structure is disposed to implement the first optical layer having a sufficient thickness between a solder pattern and a second electrode.

Various embodiments of the present disclosure provide a display device in which a first optical layer of a multilayer structure includes different layers having different particles of different materials and different particle sizes, thereby improving light extraction efficiency of the device.

Technical benefits according to the present disclosure are not limited to the above-mentioned benefits. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A display device according to embodiments of the present disclosure may include a substrate including a plurality of pixels; a plurality of pixel driving circuits respectively disposed on the plurality of pixels of the substrate; a plurality of banks disposed on each of the pixel driving circuits; a plurality of light-emitting elements respectively disposed on the plurality of banks; solder patterns disposed on the plurality of banks, wherein at least some of the solder patterns are respectively bonded to the plurality of light-emitting elements; an optical layer disposed on the plurality of banks; an electrode disposed on the plurality of light-emitting elements and the optical layer, wherein the optical layer is disposed between the solder pattern and the electrode.

A display device according to embodiments of the present disclosure may include a substrate including a plurality of pixels; a plurality of pixel driving circuits respectively disposed on the plurality of pixels of the substrate; a plurality of banks disposed on each of the pixel driving circuits; a plurality of light-emitting elements respectively disposed on the plurality of banks; solder patterns disposed on the plurality of banks, wherein at least some of the solder patterns are respectively bonded to the plurality of light-emitting elements; an optical layer disposed on the plurality of banks; and an electrode disposed on the optical layer and the plurality of light-emitting elements, wherein the optical layer is disposed between the solder pattern and the electrode, wherein the optical layer has a multi-layer structure.

According to an embodiment of the present disclosure, the electrical short circuit may be prevented from occurring between the first electrode and the second electrode by disposing the first optical layer between the solder pattern to which the light-emitting element is not bonded and the second electrode.

In addition, the first optical layer is composed of a multilayer structure, such that the first optical layer having a sufficient thickness is disposed between the solder pattern and the second electrode, thereby preventing an electrical short circuit from occurring between the first electrode and the second electrode.

In addition, the first optical layer of the multilayer structure may include different layers having different particles of different particle sizes to prevent the light from being extinguished out. Accordingly, the path of light may be changed to increase the amount of light emitted to the outside, such that light extraction efficiency of the device may be improved. Improving the light extraction efficiency may allow the display device to operate at a low power level to reduce power consumption thereof.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF THE SEVERAL VIEWS OF THE DRAWINGS

FIG. 1 is an exploded perspective view of a display device according to an embodiment of the present disclosure.

FIG. 2 is a plan view of a display device according to an embodiment of the present disclosure.

FIG. 3 is an enlarged view of a display device according to an embodiment of the present disclosure.

FIG. 4 is a diagram illustrating a circuit structure according to an embodiment of the present disclosure.

FIG. 5 is a plan view of a display device according to an embodiment of the present disclosure.

FIG. 6 is a plan view of a display device according to an embodiment of the present disclosure.

FIG. 7 is a plan view of a display device according to an embodiment of the present disclosure.

FIG. 8 is a cross-sectional view of a display device according to an embodiment of the present disclosure.

FIG. 9 is a cross-sectional view of a display device according to an embodiment of the present disclosure.

FIGS. 10 to 13 are diagrams illustrating an apparatus to which a display device according to embodiments of the present disclosure is applied.

FIG. 14 is a plan view illustrating an area in which one pixel driving circuit among a plurality of pixel driving circuits is disposed.

FIGS. 15A to 15D are diagrams illustrating a method for manufacturing a display device according to an embodiment of the present disclosure.

FIG. 16 is an enlarged cross-sectional view of a portion of each of a plurality of sub-pixels of a display device according to an embodiment of the present disclosure.

FIGS. 17 and 18 are enlarged cross-sectional views of one sub-pixel of a display device according to another embodiment of the present disclosure.

FIGS. 19A to 19D are diagrams illustrating a method for manufacturing a display device according to another embodiment of the present disclosure.

FIGS. 20 and 21 are enlarged cross-sectional views of one sub-pixel of a display device according to another embodiment of the present disclosure.

FIGS. 22A to 22E are diagrams illustrating a method for manufacturing a display device according to still another embodiment of the present disclosure.

### DETAILED DESCRIPTIONS

Advantages and features of the present disclosure, and a method of achieving the advantages and features will become apparent with reference to embodiments described below in detail together with the accompanying drawings. However, the present disclosure is not limited to the embodiments as disclosed under, but may be implemented in various different forms. Thus, these embodiments are set forth only to make the present disclosure complete, and to entirely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise,” “comprising,” “include,” and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items.

Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when a first element or layer is referred to as being “connected to,” or “coupled to” a second element or layer, the first element may be directly connected to or coupled to the second element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present therebetween.

Further, as used herein, the terms “connected” and “coupled” are intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” should be interpreted in the same manner.

Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after,” “subsequent to,” “before,” etc., another event may occur therebetween unless “directly after,” “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first,” “second,” “third,” and so on may be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, etc., should not be construed such that any aspect or design as described is superior to or advantageous over other aspects or designs.

Further, the term ‘or’ means ‘inclusive or’ rather than ‘exclusive or.’ That is, unless otherwise stated or clear from the context, the expression that ‘x uses a or b’ means one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

Throughout the present disclosure, “A and/or B” means A, B, or A and B, unless otherwise specified, and “C to D” means C inclusive to D inclusive unless otherwise specified.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally.

Hereinafter, various embodiments of the present disclosure will be described in detail with reference to the accompanying drawings.

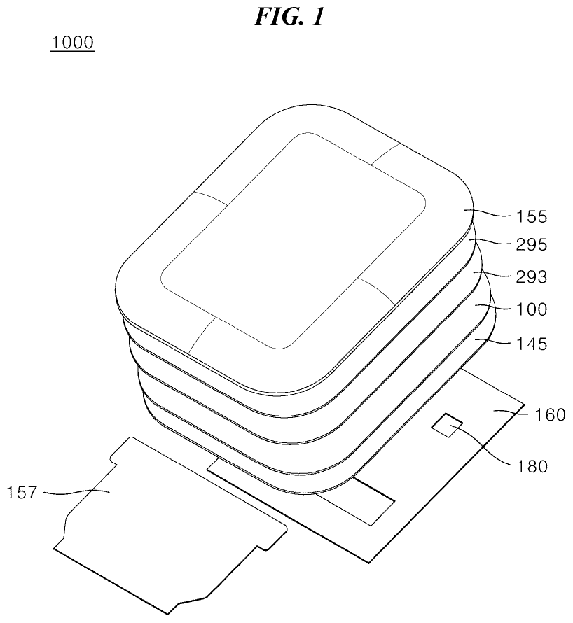

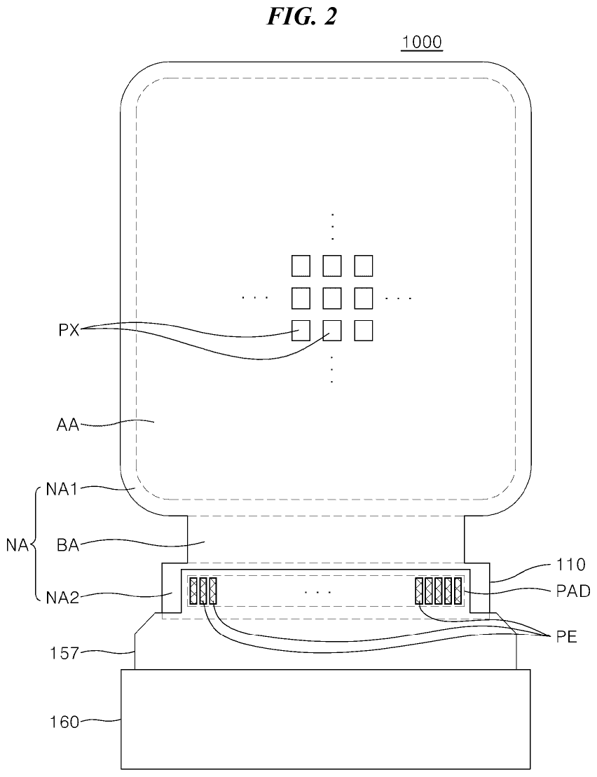

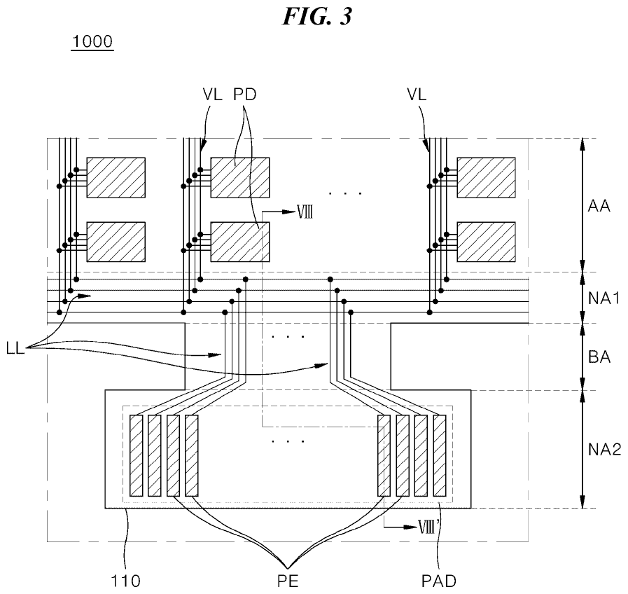

FIG. 1 is an exploded perspective view of a display device according to an embodiment of the present disclosure. FIG. 2 is a plan view of a display device according to an embodiment of the present disclosure. FIG. 3 is an enlarged view of a display device according to an embodiment of the present disclosure.

Referring to FIGS. 1 to 3, a display device 1000 according to an embodiment of the present disclosure may include a display panel 100, a polarizing layer 293, an adhesive layer 295, a cover member 155, a support substrate 145, a flexible circuit board 157, and a printed circuit board 160.

For example, the display device 1000 may include a substrate 110. The substrate 110 may be a member supporting other components of the display device 100. The substrate 110 may be made of an insulating material. For example, the substrate 110 may be made of glass or resin. In addition, the substrate 110 may be made of a material having flexibility. For example, the substrate 110 may be made of a plastic material having flexibility, such as polyimide (PI). However, embodiments of the present disclosure are not limited thereto.

The display panel 100 may implement information, a video, and/or an image to be provided to a user. For example, the display panel 100 may include a display area AA and a non-display area NA. For example, the substrate 110 may include the display area AA and the non-display area NA. The distinction between the display area AA and the non-display area NA is applied not only to the substrate 110 but also to the display device 1000.

The display area AA may be an area in which an image is displayed. The display area AA may include a plurality of pixels PX. Each of the plurality of pixels PX may be composed of a plurality of sub-pixels. A plurality of light-emitting elements may be disposed in each of the plurality of sub-pixels SP. A type of each of the plurality of light-emitting elements may vary according to a type of the display device 1000. For example, when the display device 1000 is an inorganic light-emitting display device, the light-emitting element may be a light-emitting diode (LED), a micro light-emitting diode (LED), or a mini light-emitting diode (LED). However, embodiments of the present disclosure are not limited thereto.

The non-display area NA may be an area in which no image is displayed. Various lines and circuits for driving the plurality of pixels PX of the display area AA may be disposed in the non-display area NAA. For example, various wires and driving circuits may be mounted in the non-display area NA, and a pad PAD to which an integrated circuit, a printed circuit, etc., are connected may be disposed in the non-display area NA. However, embodiments of the present disclosure are not limited thereto.

For example, the driving circuit may be a data driving circuit and/or a gate driving circuit. However, embodiments of the present disclosure are not limited thereto. Wires to which a control signal for controlling the driving circuits is supplied may be disposed. For example, the control signal may include various timing signals including a clock signal, an input data enable signal, and synchronization signals. However, embodiments of the present disclosure are not limited thereto. The control signal may be received via the pad PAD. For example, link lines LL for transmitting signals may be disposed in the non-display area NA. For example, driving components such as a flexible printed circuit board 157 and a printed circuit board 160 may be connected to the pad PAD.

According to the present disclosure, the non-display area NA may include a first non-display area NA1, a bending area BA, and a second non-display area NA2. For example, the first non-display area NA1 may be an area surrounding at least a portion of the display area AA. The bending area BA is an area extending from at least one of a plurality of sides of the first non-display area NA1 and may be a bendable area. The second non-display area NA2 may be an area extending from the bending area BA, and the pad PAD may be disposed in the second non-display area. For example, the bending area BA may be in a bent state, and the remaining area of the substrate 110 except for the bending area BA may be in a flat state. In this case, as the bending area BA is bent, the second non-display area NA2 may be located on a rear surface of the display area AA. However, embodiments of the present disclosure are not limited thereto.

The display area AA of the substrate 110 or the display device 1000 may be formed in various shapes according to the designs of the display device 1000. For example, the display area AA may be formed in a rectangular shape having four corners of a round shape. However, embodiments of the present disclosure are not limited thereto. In another example, the display area AA may be formed in a rectangular shape in which four corners have a right angle or a circular shape. However, embodiments of the present disclosure are not limited thereto.

According to the present disclosure, a width of the second non-display area NA2 in which a plurality of pad electrodes PE are disposed may be greater than a width of the bending area BA in which only a plurality of link lines LL are disposed. In addition, the width of the display area AA in which the plurality of sub-pixels are disposed may be greater than the width of the bending area BA in which only the plurality of link lines LL are disposed. Although the width of the bending area BA is illustrated as being smaller than the width of the remaining area of the substrate 110 in the drawing, a shape of the substrate 110 including the bending area BA is merely an example, and embodiments of the present disclosure are not limited thereto.

Referring to FIG. 3, a plurality of pixel driving circuits PD may be disposed in the display area AA. The plurality of pixel driving circuits PD may be circuits for driving the light-emitting elements of the plurality of sub-pixels. Each of the plurality of pixel driving circuits PD may include a plurality of transistors including a driving transistor, a storage capacitor, etc., and may control an emission operation of the plurality of light-emitting elements by supplying a control signal, a power, and a driving current to the light-emitting elements of the plurality of sub-pixels. For example, the pixel driving circuit PD may include a power line and a signal line for controlling the emission on/off and/or emission time of the light-emitting element. For example, each of the plurality of pixel driving circuits PD may be a driver manufactured using a metal-oxide-silicon field effect transistor (MOSFET) manufacturing process and disposed on a semiconductor substrate. However, embodiments of the present disclosure are not limited thereto. A driver may include the plurality of pixel driving circuits PD and may drive the plurality of sub-pixels. For example, the plurality of pixel driving circuits PD may include a micro driver (Driver). However, embodiments of the present disclosure are not limited thereto. For example, each of the plurality of pixel driving circuits PD may include a driving chip. However, embodiments of the present disclosure are not limited thereto.

Referring to FIG. 1 and FIG. 2, the flexible circuit board 157 and the printed circuit board 160 may be disposed under the display panel 100. The flexible circuit board 157 and the printed circuit board 160 may be disposed at least at one edge of the display panel 100. However, embodiments of the present disclosure are not limited thereto. One side of the flexible circuit board 157 may be attached to the display panel 100 and the other side thereof may be attached to the printed circuit board 160. However, embodiments of the present disclosure are not limited thereto. The flexible circuit board 157 may be a flexible film. However, embodiments of the present disclosure are not limited thereto.

The pad PAD including a plurality of pad electrodes PE may be disposed in the second non-display area NA2. A driving component including one or more flexible circuit boards (or flexible films) 157 and the printed circuit board 160 may be attached or bonded to the pad PAD. The plurality of pad electrodes PE of the pad PAD may be electrically connected to one or more flexible circuit boards (or flexible films) 157, and may transmit various signals (or power) from the printed circuit board 160 and the flexible circuit boards (or flexible films) 157 to the plurality of pixel driving circuits PD of the display area AA.

The flexible circuit board (or flexible film) 157 may be a film in which various components are disposed on a flexible base film. For example, a driving IC such as a gate driver IC or a data driver IC may be disposed on the flexible circuit board (or flexible film) 157. However, embodiments of the present disclosure are not limited thereto. The driving IC DT may be a component that processes data for displaying an image and a driving signal. The driving IC DT may be disposed in a manner such as a Chip On Glass (COG), a Chip On Film (COF), or a Tape Carrier Package (TCP) according to a mounted manner. However, embodiments of the present disclosure are not limited thereto. The flexible circuit board (or flexible film) 157 may be attached or bonded to the plurality of pad electrodes PE via a conductive adhesive layer. However, embodiments of the present disclosure are not limited thereto.

The printed circuit board 160 may be electrically connected to one or more flexible circuit boards (or flexible films) 157 and may be a component that supplies a signal to the driving IC. The printed circuit board 160 may be disposed on one side of the flexible circuit board (or flexible film) 157 so as to be electrically connected to the flexible circuit board (or flexible film) 157. Various components for supplying various signals to the driving IC may be disposed on the printed circuit board 160. For example, various components such as a timing controller, a power supply unit, a memory, or a processor may be disposed on the printed circuit board 160. For example, the printed circuit board 160 may include a power management integrated circuit (PMIC). However, embodiments of the present disclosure are not limited thereto.

The printed circuit board 160 may include at least one hole 180. However, embodiments of the present disclosure are not limited thereto. An internal component for sensing ambient light or temperature that may be provided to the plurality of sensors may be disposed in an area corresponding to the at least one hole 180. For example, the internal component may include an ALS (Ambient light sensor), a temperature sensor, etc. However, embodiments of the present disclosure are not limited thereto. For example, the hole 180 may be a transmission hole or the like. However, embodiments of the present disclosure are not limited thereto.

Referring to FIG. 1, the polarizing layer 293 may be disposed on the display panel 100. The polarizing layer 293 may prevent or reduce light generated from an external light source from entering the display panel 100 and thus affecting the light-emitting element or the like.

The cover member 155 may be disposed on the polarizing layer 293. The cover member 155 may be a member for protecting the display panel 100. The adhesive layer 295 may be disposed between the polarizing layer 293 and the cover member 155. The cover member 155 may be attached to the display panel 100 via the adhesive layer 295. The adhesive layer 295 may include an OCA (Optically clear adhesive), an OCR (Optically clear resin), a PSA (Pressure sensitive adhesive), etc. However, embodiments of the present disclosure are not limited thereto.

The support substrate 145 may be disposed between the display panel 100 and the printed circuit board 160. The support substrate 145 may reinforce the rigidity of the display panel 100. The support substrate 145 may be a back plate. However, embodiments of the present disclosure are not limited thereto.

Referring to FIGS. 1 to 3, the plurality of link lines LL may be disposed in the non-display area NA. The plurality of link lines LL may be lines for transmitting various signals from one or more flexible circuit boards (or flexible films) 157 and the printed circuit board 160 to the display area AA. The plurality of link lines LL may extend from the plurality of pad electrodes PE of the second non-display area NA2 toward the bending area BA and the first non-display area NA1 and may be electrically connected to the plurality of driving lines VL of the display area AA. The plurality of pixel driving circuits PD may be driven upon receiving signals from one or more flexible circuit boards (or flexible films) 157 and the printed circuit boards 160 via driving lines VL of the display area AA and the link lines LL of the non-display area NA.

For example, a plurality of driving lines VL together with the plurality of link lines LL may transmit signals output from the flexible circuit board (or flexible film) 157 and the printed circuit board 160 to the plurality of pixel driving circuits PD. The plurality of driving lines VL may be disposed in the display area AA and may be electrically connected to each of the plurality of pixel driving circuits PD. The plurality of driving lines VL may extend from the display area AA toward the non-display area NA and may be electrically connected to the plurality of link lines LL. Accordingly, the signals output from the flexible circuit board (or flexible film) 157 and the printed circuit board 160 may be transmitted to each of the plurality of pixel driving circuits PD via the plurality of link lines LL and the plurality of driving lines VL.

As the bending area BA is bent, a portion of each of the plurality of link lines LL may also be bent. Thus, stress is concentrated on a portion of the bent link line LL, and accordingly, a crack may occur in the link line LL. Accordingly, the plurality of link lines LL may be made of a conductive material having excellent ductility to reduce the cracks occurring when the bending area BA is bent. For example, the plurality of link lines LL may be made of a conductive material having excellent ductility, such as gold (Au), silver (Ag), aluminum (Al), etc. However, embodiments of the present disclosure are not limited thereto. In addition, the plurality of link lines LL may be made of one of various conductive materials used in the display area AA. For example, the plurality of link lines LL may be made of molybdenum (Mo), chromium (Cr), titanium (Ti), nickel (Ni), neodymium (Nd), copper (Cu), an alloy thereof, or an alloy of silver (Ag) and magnesium (Mg). However, embodiments of the present disclosure are not limited thereto. The plurality of link lines LL may be configured in a multilayer structure including various conductive materials. For example, the plurality of link lines LL may be configured in a triple layer structure of a titanium (Ti) layer/aluminum (Al) layer/titanium (Ti) layer. However, embodiments of the present disclosure are not limited thereto.

The plurality of link lines LL may be formed in various shapes to reduce the stress. At least a portion of each of the plurality of link lines LL disposed on the bending area BA may extend in the same direction as an extending direction of the bending area BA, or may extend in a direction different from the extending direction of the bending area BA to reduce the stress. For example, when the bending area BA extends in one direction from the first non-display area NA1 toward the second non-display area NA2, at least a portion of the link line LL disposed on the bending area BA may extend in a direction inclined with respect to the one direction. In another example, at least a portion of each of the plurality of link lines LL may be formed in each of patterns of various shapes. For example, at least a portion of each of the plurality of link lines LL disposed on the bending area BA may have a shape in which conductive patterns having at least one of a diamond shape, a rhombus shape, a trapezoidal shape, a triangular wave shape, a sawtooth wave shape, a sine wave shape, a circular shape, and an omega (Q) shape are repeatedly arranged. However, embodiments of the present disclosure are not limited thereto. Therefore, in order to minimize the stress concentrated on the plurality of link lines LL and the resulting crack, the shape of each of the plurality of link lines LL may be formed in various shapes including the above-described shape. However, embodiments of the present disclosure are not limited thereto.

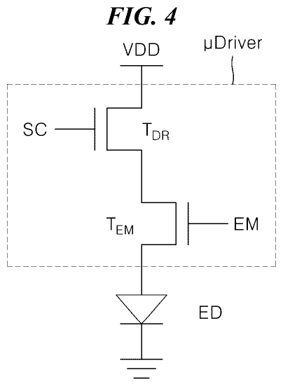

FIG. 4 is a diagram illustrating a circuit structure according to an embodiment of the present disclosure.

FIG. 4 illustrates that one light-emitting element ED is connected to the micro driver Driver. However, embodiments of the present disclosure are not limited thereto. For example, eight light-emitting elements LED may be connected to one micro driver μDriver. In another example, 16 light-emitting elements ED may be connected to one micro driver μDriver, or 32 light-emitting elements ED or 64 light-emitting elements ED may be simultaneously connected to one micro driver μDriver. The light-emitting element ED may be a micro light-emitting element μLED.

One micro driver μDriver may include a driving transistor TDR and a light-emission transistor TEM. However, embodiments of the present disclosure are not limited thereto.

For example, a high potential power voltage VDD may be applied to a first electrode of the driving transistor TDR, a first electrode of the light-emission transistor TEM may be connected to a second electrode of the driving transistor TDR, and a scan signal SC may be applied to a gate electrode of the driving transistor TDR. The scan signal SC applied to the gate electrode of the driving transistor TDR is a direct current power, and a fixed reference voltage Vref may be applied thereto every frame. However, embodiments of the present disclosure are not limited thereto.

The second electrode of the driving transistor TDR may be connected to the first electrode of the light-emission transistor TEM, the light-emitting element ED may be connected to a second electrode of the light-emission transistor TEM, and the light-emission signal EM may be applied to a gate electrode of the light-emission transistor TEM. The light-emission signal EM applied to the gate electrode of the light-emission transistor TEM may be a pulse width modulation signal that varies in every frame. However, embodiments of the present disclosure are not limited thereto.

The light-emitting element ED may have a first electrode connected to the second electrode of the light-emission transistor TEM, and a second electrode connected to the ground. For example, the first electrode thereof may be an anode electrode, and the second electrode thereof may be a cathode electrode. However, embodiments of the present disclosure are not limited thereto.

Each of the driving transistor TDR and the light-emission transistor TEM may be an n-type transistor or a p-type transistor.

In the micro driver μDriver, the driving transistor TDR may be turned on based on the scan signal SC applied thereto from a timing controller T-CON, and the light-emission transistor TEM may be turned on based on the light-emission signal EM. Accordingly, the driving current is applied to the light-emitting element ED via the driving transistor TDR and the light-emission transistor TEM based on the high potential power voltage VDD applied to the first electrode of the driving transistor TDR, so that the light-emitting element ED may emit light.

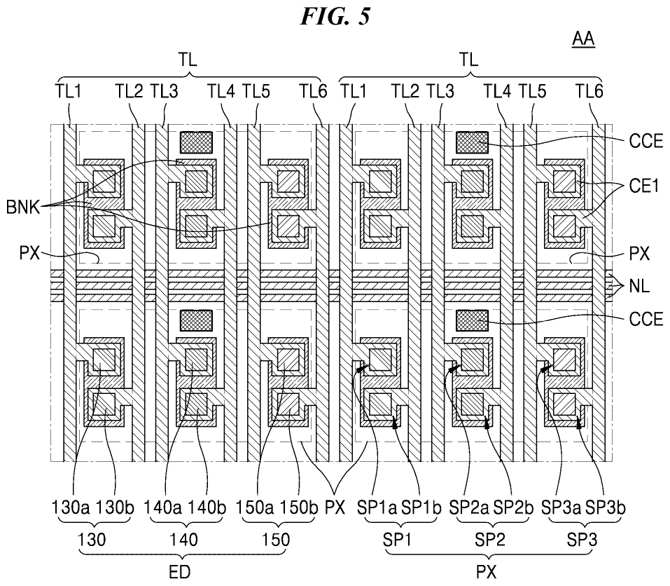

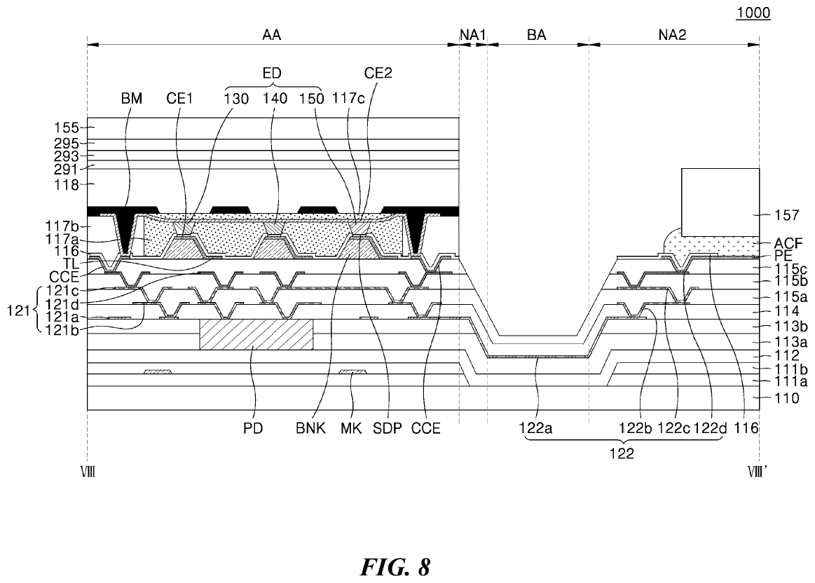

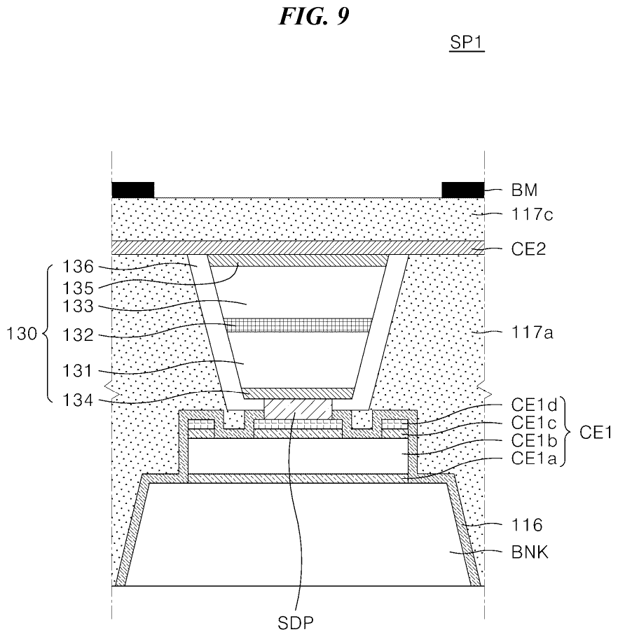

FIGS. 5 to 7 are plan views of a display device according to an embodiment of the present disclosure. FIGS. 8 and 9 are cross-sectional views of a display device according to an embodiment of the present disclosure.

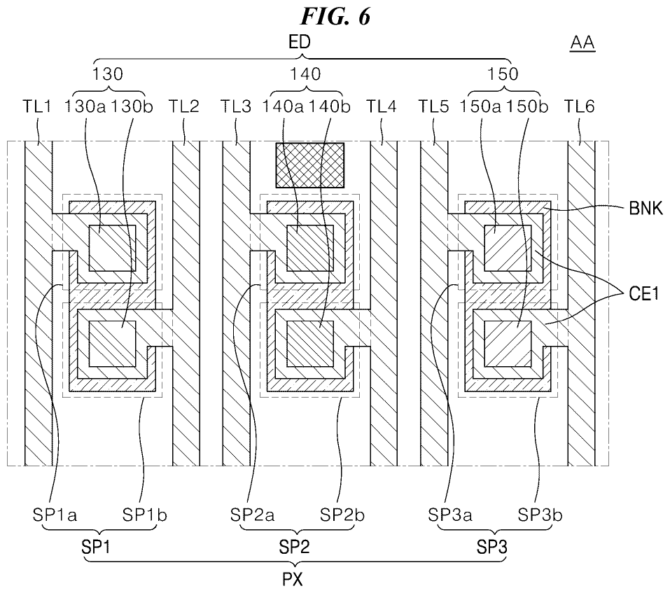

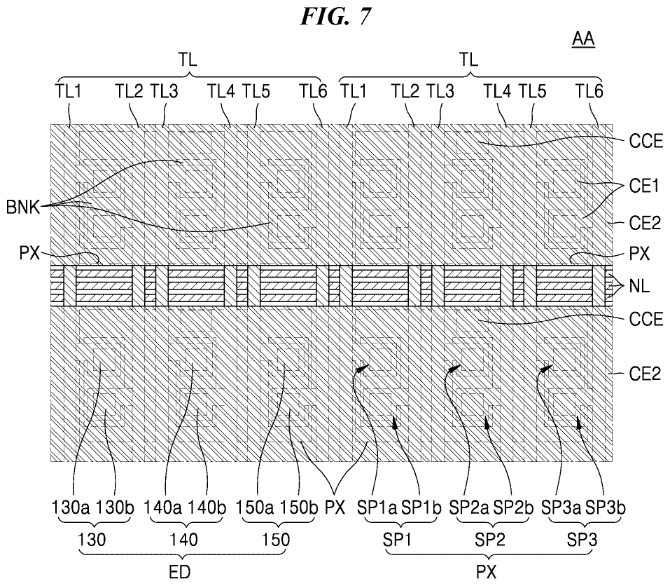

For example, FIG. 5 is an enlarged plan view of a display area including a plurality of pixels. For example, FIG. 6 is an enlarged plan view of a display area including one pixel. For example, FIG. 7 is an enlarged plan view of a display area including a plurality of pixels. For example, FIG. 8 is a cross-sectional view of the display area AA, the first non-display area NA1, the bending area BA, and the second non-display area NA2. For example, FIG. 9 is a cross-sectional view of a display area including one sub-pixel SP1. FIG. 8 is a cross-sectional view of the display device taken along a line VIII-III′ of FIG. 3. For convenience of illustration, FIG. 3 illustrates that a cutting line VIII-VIII′ and the driving line VL and the link line LL do not overlap each other. However, the present disclosure is not limited thereto. The cutting line VIII-VIII′ of FIG. 3 is intended for indicating that a position thereof is the same as that of each of the driving line VL and the link line LL adjacent thereto.

FIGS. 5 and 6 illustrate only a plurality of signal lines TL, a plurality of communication lines NL, a plurality of first electrodes CE1, a plurality of banks BNK, and a plurality of light-emitting elements ED. However, embodiments of the present disclosure are not limited thereto. FIG. 7 is an enlarged plan view in which a plurality of second electrodes CE2 are additionally disposed in FIG. 5.

Referring to FIGS. 5, 6, and 9, a plurality of pixels PX, each including a plurality of sub-pixels, may be disposed in the display area AA. Each of the plurality of sub-pixels includes a light-emitting element ED, and may independently emit light. The plurality of sub-pixels may be arranged in a plurality of rows and a plurality of columns and thus may be arranged in a matrix form. However, embodiments of the present disclosure are not limited thereto.

The plurality of sub-pixels may include a first sub-pixel SP1, a second sub-pixel SP2, and a third sub-pixel SP3. For example, one of the first sub-pixel SP1, the second sub-pixel SP2, and the third sub-pixel SP3 may be a red sub-pixel, another thereof may be a green sub-pixel, and the other thereof may be a blue sub-pixel. A type of each of the plurality of sub-pixels is an example, and embodiments of the present disclosure are not limited thereto.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3. The pair of first sub-pixels SP1 may include a (1-1)-th sub-pixel SP1a and a (1-2)-th sub-pixel SP1b. The pair of second sub-pixels SP2 may include a (2-1)-th sub-pixel SP2a and a (2-2)-th sub-pixel SP2b. The pair of third sub-pixels SP3 may include a (3-1)-th sub-pixel SP3a and a (3-2)-th sub-pixel SP3b. For example, one pixel PX may include a (1-1)-th sub-pixel SP1a and a (1-2)-th sub-pixel SP1b, a (2-1)-th sub-pixel SP2a and a (2-2)-th sub-pixel SP2b, and a (3-1)-th sub-pixel SP3a and a (3-2)-th sub-pixel SP3b. However, embodiments of the present disclosure are not limited thereto.

The plurality of sub-pixels constituting one pixel PX may be arranged in various manner. In one example, in one pixel PX, a pair of first sub-pixels SP1 may be arranged in the same column, a pair of second sub-pixels SP2 may be arranged in the same column, and a pair of third sub-pixels SP3 may be arranged in the same column. The first sub-pixel SP1, the second sub-pixel SP2, and the third sub-pixel SP3 may be arranged in the same row. The number and arrangement of the plurality of sub-pixels constituting one pixel PX are examples, and embodiments of the present disclosure are not limited thereto.

A plurality of signal lines TL may be disposed in an area between adjacent ones of the plurality of sub-pixels. The plurality of signal lines TL may extend in the column direction while being disposed between adjacent ones of the plurality of sub-pixels. The plurality of signal lines TL may be lines for transmitting an anode voltage from the pixel driving circuit PD to the plurality of sub-pixels. For example, the plurality of signal lines TL may be electrically connected to the plurality of pixel driving circuits PD and the first electrodes CE1 of the plurality of sub-pixels. The anode voltage output from the pixel driving circuit PD may be transmitted to the first electrodes CE1 of the plurality of sub-pixels via the plurality of signal lines TL. For example, the first electrode CE1 may be an electrode electrically connected to the anode electrode 134 of the light-emitting element ED. Accordingly, the anode voltage from the signal line TL may be transmitted to the anode electrode 134 of the light-emitting element ED via the first electrode CE1.

Therefore, a structure of the display device 1000 may be simplified using the pixel driving circuit PD in which the plurality of pixel circuits are integrated with each other, instead of forming a plurality of transistors and a storage capacitor in each of the plurality of sub-pixels. In addition, as circuits respectively disposed in the plurality of sub-pixels are integrated into one pixel driving circuit PD, high-efficiency low-power operation of the display device may be achieved.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may be electrically connected to the pair of first sub-pixels SP1, respectively. The third signal line TL3 and the fourth signal line TL4 may be electrically connected to the pair of second sub-pixels SP2, respectively. The fifth signal line TL5 and the sixth signal line TL6 may be electrically connected to the pair of third sub-pixels SP3, respectively.

The first signal line TL1 may be disposed on one side of the pair of first sub-pixels SP1, and the first signal line TL1 may be disposed on the other side of the pair of first sub-pixels SP1. The first signal line TL1 may be electrically connected to one first sub-pixel SP1 of the pair of first sub-pixels SP1, for example, the first electrode CE1 of the (1-1)-th sub-pixel SP1a. The second signal line TL2 may be electrically connected to the other first sub-pixel SP1 of the pair of first sub-pixels SP1, for example, the first electrode CE1 of the (1-2)-th sub-pixel SP1b.

The third signal line TL3 may be disposed on one side of the pair of second sub-pixels SP2, and the fourth signal line TL4 may be disposed on the other side of the pair of second sub-pixels SP2. For example, the third signal line TL3 may be disposed adjacent to the second signal line TL2. The third signal line TL3 may be electrically connected to one second sub-pixel SP2 of the pair of second sub-pixels SP2, for example, the first electrode CE1 of the (2-1)-th sub-pixel SP2a. The fourth signal line TL4 may be electrically connected to the other second sub-pixel SP2 of the pair of second sub-pixels SP2, for example, the first electrode CE1 of the (2-2)-th sub-pixel SP2b.

The fifth signal line TL5 may be disposed on one side of the pair of third sub-pixels SP3, and a sixth signal line TL6 may be disposed on the other side of the pair of third sub-pixels SP3. For example, the fifth signal line TL5 may be disposed adjacent to the fourth signal line TL4. The sixth signal line TL6 may be disposed adjacent to the first signal line TL1 connected to the pixel PX adjacent thereto. The fifth signal line TL5 may be electrically connected to one third sub-pixel SP3 of the pair of third sub-pixels SP3, for example, the first electrode CE1 of the (3-1)-th sub-pixel SP3a. The sixth signal line TL6 may be electrically connected to the other third sub-pixel SP3 of the pair of third sub-pixels SP3, for example, the first electrode CE1 of the (3-2)-th sub-pixel SP3b.

Each of the plurality of signal lines TL may be made of a conductive material. For example, each of the plurality of signal lines TL may be made of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc. However, embodiments of the present disclosure are not limited thereto. In another example, each of the plurality of signal lines TL may have a multilayer structure made of a conductive material. For example, each of the plurality of signal lines TL may have a multilayer structure of a titanium (Ti) layer/aluminum (Al) layer/titanium (Ti) layer/indium tin oxide (ITO) layer. However, embodiments of the present disclosure are not limited thereto.

A plurality of communication lines NL may be disposed in an area between adjacent ones of the plurality of pixels PX. The plurality of communication lines NL may extend in the row direction while being disposed in an area between adjacent ones of the plurality of pixels PX. The plurality of communication lines NL may be disposed in an area between adjacent ones of the plurality of second electrodes CE2 and may not overlap the plurality of second electrodes CE2. For example, the plurality of communication lines NL may be lines used for short-range communication such as near field communication (NFC). The plurality of communication lines NL may function as antennas. For example, the plurality of communication lines NL may be a plurality of connection lines, etc. However, embodiments of the present disclosure are not limited thereto.

According to the present disclosure, a bank BNK may be disposed in each of the plurality of sub-pixels. Each of the plurality of banks BNK may be a structure in which each of the plurality of light-emitting elements ED is seated. The plurality of banks BNK may guide positions of the plurality of light-emitting elements ED in a transfer process of transferring the plurality of light-emitting elements ED to the substrate, respectively. In the transfer process of the plurality of light-emitting elements ED thereto, the plurality of light-emitting elements ED may be transferred onto the plurality of banks BNK, respectively. The plurality of banks BNK may be bank patterns, structures, etc. However, embodiments of the present disclosure are not limited thereto.

The bank BNK of the first sub-pixel SP1, the bank BNK of the second sub-pixel SP2, and the bank BNK of the third sub-pixel SP3 may be spaced apart from each other. The bank BNK of the first sub-pixel SP1, the bank BNK of the second sub-pixel SP2, and the bank BNK of the third sub-pixel SP3 may be constructed to be isolated from each other. Accordingly, the banks BNK of the first sub-pixel SP1, the second sub-pixel SP2, and the third sub-pixel SP3 to which different types of light-emitting elements ED are transferred, respectively may be easily identified.

The bank BNK of the (1-1)-th sub-pixel SP1a and the bank BNK of the (1-2)-th sub-pixel SP1b may be connected to each other, or may be spaced apart or isolated from each other. For example, the bank BNK of the (1-1)-th sub-pixel SP1a and the bank BNK of the (1-2)-th sub-pixel SP1b in which the light-emitting elements ED of the same type are disposed, respectively may be connected to each other, or may be spaced apart or isolated from each other in consideration of a design such as a transfer process requirement. In addition, the bank BNK of the (2-1)-th sub-pixel SP2a and the bank BNK of the (2-2)-th sub-pixel SP2b may be connected to each other, or may be spaced apart or isolated from each other. The bank BNK of the (3-1)-th sub-pixel SP3a and the bank BNK of the (3-2)-th sub-pixel SP3b may be connected to each other, or may be spaced apart or isolated from each other. Accordingly, the banks BNK of the pair of first sub-pixels SP1, the banks BNK of the pair of second sub-pixels SP2, and the banks BNK of the pair of third sub-pixels SP3 may be variously formed. Embodiments of the present disclosure are not limited thereto.

For example, each of the plurality of banks BNK may be made of an organic insulating material. Each of the plurality of banks BNK may be formed as a single layer or multiple layers made of an organic insulating material. For example, each of the plurality of banks BNK may be made of photoresist, polyimide (PI), or an acryl-based material. However, embodiments of the present disclosure are not limited thereto.

The first electrode CE1 may be disposed in each of the plurality of sub-pixels SP. The first electrode CE1 may be disposed on the bank BNK. The first electrode CE1 may be electrically connected to one signal line TL among the plurality of signal lines TL. At least a portion of the first electrode CE1 may extend outwardly of the bank BNK and may be electrically connected to the signal line TL closest to the first electrode CE1. For example, a portion of the first electrode CE1 of the (1-1)-th sub-pixel SP1a may extend to one side area of the (1-1)-th sub-pixel SP1a so as to be electrically connected to the first signal line TL1, and a portion of the first electrode CE1 of the (1-2)-th sub-pixel SP1b may extend to the other side area of the (1-2)-th sub-pixel SP1b so as to be electrically connected to the second signal line TL2. A portion of the first electrode CE1 of the (2-1)-th sub-pixel SP2a may extend to one side area of the (2-1)-th sub-pixel SP2a so as to be electrically connected to the third signal line TL3, and a portion of the first electrode CE1 of the (2-1)-th sub-pixel SP2b may extend to the other side area of the (2-1)-th sub-pixel SP2b so as to be electrically connected to the fourth signal line TL4. A portion of the first electrode CE1 of the (3-1)-th sub-pixel SP3a may extend to one side area of the (3-1)-th sub-pixel SP3a so as to be electrically connected to the fifth signal line TL5, and a portion of the first electrode CE1 of the (3-2)-th sub-pixel SP3b may extend to the other side area of the (3-2)-th sub-pixel SP3b so as to be electrically connected to the sixth signal line TL6.

The first electrode CE1 may be electrically connected to the anode electrode 134 of the light-emitting element ED, and may transmit an anode voltage from the pixel driving circuit PD to the light-emitting element ED via the signal line TL. Different voltages may be respectively applied to the first electrodes CE1 of the plurality of sub-pixels based on a displayed image. For example, different voltages may be applied to the first electrodes CE1 of the plurality of sub-pixels SP, respectively. Accordingly, the first electrode CE1 may be a pixel electrode, and embodiments of the present disclosure are not limited thereto.

The first electrode CE1 may be made of a conductive material. For example, the first electrode CE1 may be integrally formed with the plurality of signal lines TL. For example, the first electrode CE1 may be made of the same conductive material as that of each of the plurality of signal lines TL. However, embodiments of the present disclosure are not limited thereto. For example, the first electrode CE1 may be made of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc. However, embodiments of the present disclosure are not limited thereto. In another example, the first electrode CE1 may be configured to have a multilayer structure made of a conductive material. For example, each of the plurality of first electrodes CE1 may have a multilayer structure of a titanium (Ti) layer/aluminum (Al) layer/titanium (Ti) layer/indium tin oxide (ITO) layer. However, embodiments of the present disclosure are not limited thereto.

The light-emitting element ED may be disposed in each of the plurality of sub-pixels. The plurality of light-emitting elements ED may be one of a light-emitting diode (LED) or a micro light-emitting diode (LED). However, embodiments of the present disclosure are not limited thereto. The plurality of light-emitting elements ED may be disposed on the bank BNK and the first electrode CE1. The plurality of light-emitting elements ED may be disposed on the first electrode CE1 and may be electrically connected to the first electrode CE1. Accordingly, the light-emitting element ED may receive the anode voltage from the pixel driving circuit PD via the signal line TL and the first electrode CE1 to emit light.

The plurality of light-emitting elements ED may include a first light-emitting element 130, a second light-emitting element 140, and a third light-emitting element 150. The first light-emitting element 130 may be disposed in the first sub-pixel SP1. The second light-emitting element 140 may be disposed in the second sub-pixel SP2. The third light-emitting element 150 may be disposed in the third sub-pixel SP3. For example, one of the first light-emitting element 130, the second light-emitting element 140, and the third light-emitting element 150 may be a red light-emitting element, another thereof may be a green light-emitting element, and the other thereof may be a blue light-emitting element. However, embodiments of the present disclosure are not limited thereto. Accordingly, various colors of light including white may be implemented by combining red light, green light, and blue light respectively emitted from the plurality of light-emitting elements ED from each other. The type of each of the plurality of light-emitting elements ED is merely an example, and embodiments of the present disclosure are not limited thereto.

The first light-emitting element 130 may include a (1-1)-th light-emitting element 130a disposed in the (1-1)-th sub-pixel SP1a and a (1-2)-th light-emitting element 130b disposed in the (1-2)-th sub-pixel SP1b. The second light-emitting element 140 may include a (2-1)-th light-emitting element 140a disposed in the (2-1)-th sub-pixel SP2a and a (2-1)-th light-emitting element 140b disposed in the (2-1)-th sub-pixel SP2b. The third light-emitting element 150 may include a (3-1)-th light-emitting element 150a disposed in the (3-1)-th sub-pixel SP3a and a (3-2)-th light-emitting element 150b disposed in the (3-2)-th sub-pixel SP3b.

Referring to FIGS. 5 and 6, and FIGS. 7 and 9 together, the second electrode CE2 may be disposed in each of the plurality of sub-pixels SP. The second electrode CE2 may be disposed on the light-emitting element ED. The second electrode CE2 may be electrically connected to the pixel driving circuit PD via a plurality of contact electrodes CCE.

For example, the second electrode CE2 may be electrically connected to the cathode electrode 135 of the light-emitting element ED to transmit the cathode voltage from the pixel driving circuit PD to the light-emitting element ED. The same cathode voltage may be applied to the second electrodes CE2 of the plurality of sub-pixels SP. For example, the same voltage may be applied to the second electrodes CE2 of the plurality of sub-pixels and the cathode electrode 135 of the light-emitting element ED. Accordingly, the second electrode CE2 may be a common electrode. However, embodiments of the present disclosure are not limited thereto.

At least some of the plurality of sub-pixels may share the second electrode CE2 with each other. At least some of the second electrodes CE2 of the plurality of sub-pixels SP may be electrically connected to each other. As the same voltage is applied to the second electrodes CE2, the second electrode CE2 may be shared by the at least some sub-pixels. For example, the second electrodes CE2 of at least some pixels PX among the plurality of pixels PX disposed in the same row may be connected to each other. For example, one second electrode CE2 may be disposed in the plurality of pixels PX. One second electrode CE2 may be disposed in a combination of n sub-pixels.

For example, some of the respective second electrodes CE2 of the plurality of sub-pixels SP may be spaced apart or isolated from each other. For example, the second electrode CE2 connected to the pixels PX of an n-th row and the second electrode CE2 connected to the pixels PX of an (n+1)-th row may be spaced apart or isolated from each other. For example, adjacent ones of the plurality of second electrodes CE2 may be arranged to be spaced apart from each other while the plurality of communication lines NL extending in the row direction are disposed therebetween. Accordingly, the number of the plurality of sub-pixels may be greater than the number of the plurality of second electrodes CE2. In another example, all of the second electrodes CE2 of the plurality of sub-pixels may be connected to each other, such that only one second electrode CE2 may be disposed on the substrate 110. However, embodiments of the present disclosure are not limited thereto.

Each of the plurality of second electrodes CE2 may be made of a transparent conductive material. However, embodiments of the present disclosure are not limited thereto. Each of the plurality of second electrodes CE2 may be made of a transparent conductive material, and may allow light emitted from the light-emitting element ED to be directed upwardly of the second electrode CE2. For example, the second electrode CE2 may be made of a transparent conductive material such as Indium Tin Oxide (ITO), Indium Zinc Oxide (IZO), Indium Gallium Zinc Oxide (IGZO), etc. However, embodiments of the present disclosure are not limited thereto.

The plurality of contact electrodes CCE may be disposed on the substrate 110. For example, the plurality of contact electrodes CCE may be disposed to be spaced apart from the plurality of banks BNK and the plurality of signal lines TL. Each of the plurality of second electrodes CE2 may overlap at least one contact electrode CCE. For example, one second electrode CE2 may overlap the plurality of contact electrodes CCE.

For example, each of the plurality of contact electrodes CCE may be electrically connected to each of the plurality of second electrodes CE2. Each of the plurality of contact electrodes CCE may be disposed between the substrate 110 and each of the plurality of second electrodes CE2 to transmit the cathode voltage from the pixel driving circuit PD to each of the second electrodes CE2.

For example, when the micro LED is used as the light-emitting element ED, a plurality of micro LEDs may be formed on a wafer, and the micro LEDs may be transferred to the substrate 110 of the display device 100 to manufacture the display device 100. Various defects may occur in the process of transferring the plurality of light-emitting elements ED having a fine size from the wafer to the substrate 110. For example, a non-transfer defect in which the light-emitting element ED is not transferred may occur in some sub-pixels, and an incorrect position defect in which the light-emitting element ED is transferred out of the correct position due to an alignment error may occur in some further sub-pixels. In addition, the transfer process is normally performed, while the transferred light-emitting element ED itself may be defective. Therefore, the plurality of light-emitting elements ED of the same type may be transferred to one sub-pixel in consideration of the defect in the transfer process of the plurality of light-emitting elements ED. The lighting test of the plurality of light-emitting elements ED is performed, and only one light-emitting element ED that has been finally determined to be normal or non-defective may be used.

For example, both the (1-1)-th light-emitting element 130a and the (1-2)-th light-emitting element 130b may be transferred to one pixel PX at the same time, and whether they are defective may be inspected. When both the (1-1)-th light-emitting element 130a and the (1-2)-th light-emitting element 130b are determined to be normal or non-defective, only the (1-1)-th light-emitting element 130a may be used, and the (1-2)-th light-emitting element 130b may not be used. In another example, when only the (1-2)-th light-emitting element 130b among the (1-1)-th light-emitting element 130a and the (1-2)-th light-emitting element 130b is determined to be normal or non-defective, the (1-1)-th light-emitting element 130a may not be used and only the (1-2)-th light-emitting element 130b may be used. Therefore, even when the plurality of light-emitting elements ED of the same type are transferred to one pixel PX, only one light-emitting element ED may be finally used.

Accordingly, one of the pair of light-emitting elements ED may act as a main (primary) light-emitting element ED, and the other of the pair of light-emitting elements ED may act as a redundant light-emitting element ED. The redundant light-emitting element ED may be an extra light-emitting element ED that is transferred in preparation for the defect of the main light-emitting element ED. When the main light-emitting element ED is defective, the main light-emitting element ED may be replaced with the redundant light-emitting element ED. Accordingly, both the main light-emitting element ED and the redundant light-emitting element ED are transferred to one pixel PX at the same time, thereby minimizing a decrease in display quality due to the defect of the main light-emitting element ED and the redundant light-emitting element ED.

For example, each of the (1-1)-th light-emitting element 130a, the (2-1)-th light-emitting element 140a, and the (3-1)-th light-emitting element 150a transferred to one pixel PX may be used as the main light-emitting element ED, while each of the (1-2)-th light-emitting element 130b, the (2-2)-th light-emitting element 140b, and the (3-2)-th light-emitting element 150b may be used as the redundant light-emitting element ED.

FIG. 8 is a cross-sectional view of a display device according to an embodiment of the present disclosure. FIG. 9 is a cross-sectional view of a display device according to an embodiment of the present disclosure. For example, FIG. 8 is a cross-sectional view of the display area AA, the first non-display area NA, the bending area BA, and the second non-display area NA2. For example, FIG. 8 is a cross-sectional view taken along a cutting line 8-8 of FIG. 2. For example, FIG. 9 is a cross-sectional view of a display area including one sub-pixel SP1.

Referring to FIG. 8, a first buffer layer 111a and a second buffer layer 111b may be disposed on the remaining area of the substrate 110 except for the bending area BA.

The first buffer layer 111a and the second buffer layer 111b may be disposed in the display area AA, the first non-display area NA1, and the second non-display area NA2. The first buffer layer 111a and the second buffer layer 111b may reduce invasion of moisture or impurities through the substrate 110. Each of the first buffer layer 111a and the second buffer layer 111b may be made of an inorganic insulating material. For example, each of the first buffer layer 111a and the second buffer layer 111b may be formed as a single layer or multiple layers made of silicon oxide (SiOₓ) or silicon nitride (SiNₓ). However, embodiments of the present disclosure are not limited thereto.

For example, a portion of each of the first buffer layer 111a and the second buffer layer 111b in the bending area BA may be removed. An upper surface of a portion of the substrate 110 located in the bending area BA may be not covered with the first buffer layer 111a and the second buffer layer 111b so as to be exposed. Removing the portion of each of the first buffer layer 111a and the second buffer layer 111b made of the inorganic insulating material as disposed in the bending area BA may allow cracks of the first buffer layer 111a and the second buffer layer 111b that may occur during bending to be minimized.

A plurality of alignment keys MK may be disposed between the first buffer layer 111a and the second buffer layer 111b. The plurality of alignment keys MK may be configured to identify the position of the pixel driving circuit PD during the manufacturing process of the display device 1000. For example, the plurality of alignment keys MK may be configured to correctly align the positions of the pixel driving circuits PD transferred onto the adhesive layer 112. In another example, the plurality of alignment keys MK may be omitted.

The adhesive layer 112 may be disposed on the second buffer layer 111b. The adhesive layer 112 may be disposed in the display area AA, the first non-display area NA1, the bending area BA, and the second non-display area NA2. In another example, at least a portion of the adhesive layer 112 may be removed in the non-display area NA including the bending area BA. For example, the adhesive layer 112 may be made of one of an adhesive polymer, an epoxy resin, a UV curable resin, a polyimide-based resin, an acrylate-based resin, a urethane-based resin, and polydimethylsiloxane (PDMS). However, embodiments of the present disclosure are not limited thereto.

The pixel driving circuit PD may be disposed on the adhesive layer 112 and in the display area AA. When the pixel driving circuit PD is implemented as a driver, the driver may be mounted on the adhesive layer 112 in a transfer process. However, embodiments of the present disclosure are not limited thereto.

A first protective layer 113a and a second protective layer 113b may be disposed on the adhesive layer 112 and the pixel driving circuit PD. The first protective layer 113a and the second protective layer 113b may be disposed to surround a side surface of the pixel driving circuit PD. However, embodiments of the present disclosure are not limited thereto. For example, the second protective layer 113b may be disposed to cover at least a portion of an upper surface of the pixel driving circuit PD. For example, at least one of the first protective layer 113a and the second protective layer 113b disposed on the bending area BA may be omitted. For example, the first protective layer 113a may be entirely disposed in the display area AA and the non-display area NA, and the second protective layer 113b may be partially disposed in the display area AA, the first non-display area NA1, and the second non-display area NA2. For example, a portion of the second protective layer 113b in the bending area BA may be removed. However, embodiments of the present disclosure are not limited thereto.

Each of the first protective layer 113a and the second protective layer 113b may be made of an organic insulating material. However, embodiments of the present disclosure are not limited thereto. For example, each of the first protective layer 113a and the second protective layer 113b may be made of a photoresist, polyimide (PI), or a photo acryl-based material. However, embodiments of the present disclosure are not limited thereto. For example, each of the first protective layer 113a and the second protective layer 113b may be embodied as an overcoat layer or an insulating layer. However, embodiments of the present disclosure are not limited thereto.

According to the present disclosure, a plurality of first connection lines 121 may be disposed on the second protective layer 113b and in the display area AA. The plurality of first connection lines 121 may be lines for electrically connecting the pixel driving circuit PD to other components. For example, the pixel driving circuit PD may be electrically connected to the plurality of signal lines TL and the plurality of contact electrodes CCE via the plurality of first connection lines 121. For example, the plurality of first connection lines 121 may include a (1-1)-th connection line 121a, a (1-2)-th connection line 121b, a (1-3)-th connection line 121c, and a (1-4)-th connection line 121d. However, embodiments of the present disclosure are not limited thereto.

For example, a plurality of (1-1)-th connection lines 121a may be disposed on the second protective layer 113b. The plurality of (1-1)-th connection lines 121a may be electrically connected to the pixel driving circuit PD. The plurality of (1-1)-th connection lines 121a may transmit a voltage output from the pixel driving circuit PD to the first electrode CE1 or the second electrode CE2.

For example, a third protective layer 114 may be disposed on the second protective layer 113b. The protective layer 114 may be entirely disposed in the display area AA and the non-display area NA. In the bending area BA, the third protective layer 114 may cover a side surface of the second protective layer 113b and an upper surface of the first protective layer 113a. The third protective layer 114 may be made of an organic insulating material. For example, the third protective layer 114 may be made of a photoresist, polyimide (PI), or a photo acryl-based material. However, embodiments of the present disclosure are not limited thereto. For example, the first protective layer 113a, the second protective layer 113b, and the third protective layer 114 may be made of the same material. Embodiments of the present disclosure are not limited thereto.

A plurality of (1-2)-th connection lines 121b may be disposed on the third protective layer 114. The plurality of (1-2)-th connection lines 121b may be indirectly connected to the pixel driving circuit PD or may be directly connected thereto. For example, some of the (1-2)-th connection lines 121b may be directly connected to the pixel driving circuit PD via a contact hole of the third protective layer 114. The others of the (1-2)-th connection line 121b may be electrically connected to the (1-1)-th connection line 121a via a contact hole of the third protective layer 114. However, embodiments of the present disclosure are not limited thereto. The voltage output from the pixel driving circuit PD may be transmitted to the first electrode CE1 or the second electrode CE2 via a connection line different from the plurality of (1-2)-th connection lines 121b.

A first insulating layer 115a may be disposed on the plurality of (1-2)-th connection lines 121a. The first insulating layer 115a may be entirely disposed in the display area AA and the non-display area NA. However, embodiments of the present disclosure are not limited thereto. The first insulating layer 115a may be made of an organic insulating material. However, embodiments of the present disclosure are not limited thereto. For example, the first insulating layer 115a may be made of a photo resist, polyimide (PI), or a photo acryl-based material. However, embodiments of the present disclosure are not limited thereto.

A plurality of (1-3)-th connection lines 121c may be disposed on the first insulating layer 115a. The plurality of (1-3)-th connection lines 121c may be electrically connected to the plurality of (1-2)-th connection lines 121b, respectively. For example, the (1-3)-th connection line 121c may be electrically connected to the (1-2)-th connection line 121a via a contact hole of the first insulating layer 115a.

A second insulating layer 115b may be disposed on the plurality of (1-3)-th connection lines 121b. The second insulating layer 115b may be disposed in the remaining area except for the bending area BA. However, embodiments of the present disclosure are not limited thereto. The second insulating layer 115b may be disposed in the display area AA, the first non-display area NA1, and the second non-display area NA2. However, embodiments of the present disclosure are not limited thereto. For example, a portion of the second insulating layer 115b disposed in the bending area BA may be removed. The second insulating layer 115b may be made of an organic insulating material. However, embodiments of the present disclosure are not limited thereto. For example, the second insulating layer 115b may be made of a photo resist, polyimide (PI), or a photo acryl-based material. However, embodiments of the present disclosure are not limited thereto.

A plurality of (1-4)-th connection lines 121d may be disposed on the second insulating layer 115b. The plurality of (1-4)-th connection lines 121d may be electrically connected to the plurality of (1-3)-th connection lines 121c, respectively. For example, the (1-4)-th connection line 121d may be electrically connected to the (1-3)-th connection line 121b via a contact hole of the second insulating layer 115b.

According to the present disclosure, a plurality of second connection lines 122 may be disposed on the second protective layer 113b and in the non-display area NA. The plurality of second connection lines 122 may be lines for transmitting signals transmitted from the flexible circuit board 157 and the printed circuit board 160 (see FIG. 1) to the pad PAD to the pixel driving circuit PD of the display area AA. For example, the plurality of second connection lines 122 may be electrically connected to the plurality of pad electrodes PE respectively to receive signals from the flexible circuit board (or flexible film) 157 and the printed circuit board.

For example, the plurality of second connection lines 122 may extend from the pad PAD toward the display area AA to transmit signals to the lines of the display area AA. In this case, the plurality of second connection lines 122 may function as link lines LL. The plurality of second connection lines 122 may include a (2-1)-th connection line 122a, a (2-2)-th connection line 122b, a (2-3)-th connection line 122c, and a (2-4)-th connection line 122d.

A plurality of (2-1)-th connection lines 122a may be disposed on the second protective layer 113a. The plurality of (2-1)-th connection lines 122a may extend from the second non-display area NA2 to the bending area BA and the first non-display area NA1. The plurality of (2-1)-th connection lines 122a may transmit signals transmitted from the flexible circuit board (or flexible film) 157 and the printed circuit board to the pad PAD to the pixel driving circuit PD of the display area AA. For example, the (2-1)-th connection line 122a may be electrically connected to the pixel driving circuit PD via the first connection line 121 of the display area AA. The (2-1)-th connection line 122a may be electrically connected to the second electrode CE2 via the first connection line 121 and the contact electrode CCE of the display area AA. Accordingly, the cathode voltage may be transmitted from the pixel driving circuit PD to the light-emitting element ED via the second electrode CE2.

A plurality of (2-2)-th connection lines 122b may be disposed on the third protective layer 114. The plurality of (2-2)-th connection lines 122b may be disposed in the second non-display area NA2. The (2-2)-th connection line 122b may be electrically connected to the (2-1)-th connection line 122a via a contact hole of the third protective layer 114. Accordingly, signals from the flexible circuit board (or flexible film) 157 and the printed circuit board may be transmitted to the (2-1)-th connection line 122b via the (2-1)-th connection line 122a.

The (2-3)-th connection line 122c may be disposed on the first insulating layer 115a. The (2-3)-th connection line 122c may be disposed in the second non-display area NA2. The (2-3)-th connection line 122c may be electrically connected to the (2-2)-th connection line 122a via a contact hole of the first insulating layer 115a. Accordingly, signals from the flexible circuit board (or flexible film) 157 and the printed circuit board may be transmitted to the (2-1)-th connection line 122a via the (2-3)-th connection line 122c and the (2-2)-th connection line 122b.

The (2-4)-th connection line 122d may be disposed on the second insulating layer 115b. The (2-4)-th connection line 122d may be disposed in the second non-display area NA2. The (2-4)-th connection line 122d may be electrically connected to the (2-3)-th connection line 122b via a contact hole of the second organic insulating layer 115c. Accordingly, signals from the flexible film FF and the printed circuit board may be transmitted to the (2-1)-th connection line 122a via the (2-4)-th connection line 122d, the (2-3)-th connection line 122c, and the (2-2)-th connection line 122b.

Each of the plurality of first connection lines 121 and the plurality of second connection lines 122 may be made of a conductive material having excellent ductility or various conductive materials used in the display area AA. For example, the second connection line 122, a portion of which is disposed in the bending area BA, may be made of a conductive material having excellent ductility, such as gold (Au), silver (Ag), or aluminum (Al). However, embodiments of the present disclosure are not limited thereto. In another example, each of the plurality of first connection lines 121 and the plurality of second connection lines 122 may be made of molybdenum (Mo), chromium (Cr), titanium (Ti), nickel (Ni), neodymium (Nd), copper (Cu), an alloy of silver (Ag) and magnesium (Mg), or an alloy thereof. However, embodiments of the present disclosure are not limited thereto.

A third insulating layer 115c may be disposed on the plurality of first connection lines 121 and the plurality of second connection lines 122. The third insulating layer 115c may be disposed in the remaining area except for the bending area BA. However, embodiments of the present disclosure are not limited thereto. The third insulating layer 115c may be disposed in the display area AA, the first non-display area NA1, and the second non-display area NA2. A portion of the third insulating layer 115c in the bending area BA may be removed. The third insulating layer 115c may be made of an organic insulating material. However, embodiments of the present disclosure are not limited thereto. For example, the third insulating layer 115c may be made of a photo resist, polyimide (PI), or a photo acryl-based material. However, embodiments of the present disclosure are not limited thereto.

In the display area AA, a plurality of banks BNK may be disposed on the third insulating layer 115c. The plurality of banks BNK may be disposed to overlap the plurality of sub-pixels, respectively. One or more light-emitting elements ED of the same type may be disposed on each of the plurality of banks BNK.

In the display area AA, the plurality of signal lines TL may be disposed on the third insulating layer 115c. The plurality of signal lines TL may be disposed in an area between adjacent ones of the plurality of banks BNK. For example, the plurality of signal lines TL may be disposed adjacent to one of the plurality of banks BNK.

The plurality of contact electrodes CCE may be disposed on the third insulating layer 115c in the display area AA. The plurality of contact electrodes CCE may supply the cathode voltage from the pixel driving circuit PD to the second electrode CE2.

The first electrode CE1 may be disposed on the bank BNK. For example, the first electrode CE1 may be disposed to extend from the adjacent signal line TL toward the upper portion of the bank BNK. The first electrode CE1 may be disposed on an upper surface of the bank BNK and a side surface of the bank BNK. For example, the first electrode CE1 may be disposed to extend from the signal line TL on the upper surface of the third insulating layer 115c to the side surface of the bank BNK and the upper surface of the bank BNK.

Referring to FIG. 9, the first electrode CE1 may be made of a plurality of conductive layers. For example, the first electrode CE1 may include a first conductive layer CE1a, a second conductive layer CE1b, a third conductive layer CE1c, and a fourth conductive layer CE1d. However, embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b, and the fourth conductive layer CE1d may be disposed on the third conductive layer CE1c. For example, each of the first conductive layer CE1a, the second conductive layer CE1b, the third conductive layer CE1c, and the fourth conductive layer CE1d may be made of titanium (Ti), molybdenum (Mo), aluminum (Al), or titanium (Ti) and indium tin oxides (ITO). However, embodiments of the present disclosure are not limited thereto.

According to the present disclosure, some conductive layers having good reflection efficiency among the plurality of conductive layers constituting the first electrode CE1 may act as an alignment key for aligning the light-emitting element ED and/or a reflective plate. For example, the second conductive layer CE1b of the plurality of conductive layers of the first electrode CE1 may include a reflective material. For example, the second conductive layer CE1b may include aluminum (Al). However, embodiments of the present disclosure are not limited thereto. Accordingly, the second conductive layer CE1b may act as the reflective plate. In addition, due to the high reflection efficiency of the second conductive layer CE1b, the second conductive layer CE1b may be easily identified in the manufacturing process, and thus the position of the light-emitting element ED or the transfer position may be aligned with the second conductive layer CE1b.

For example, in order that the second conductive layer CE1b acts as the reflective plate, a portion of each of the third conductive layer CE1c and the fourth conductive layer CE1d covering the second conductive layer CE1b may be removed or etched. For example, an upper surface of the second conductive layer CE1b may be exposed by removing or etching the portion of each of the third conductive layer CE1c and the fourth conductive layer CE1d disposed on the bank BNK. For example, a central portion and an edge portion (or a rim portion) of each of the third conductive layer CE1c and the fourth conductive layer CE1d, on which a solder pattern SDP is disposed, may be left, and the remaining portion other than the central portion and the edge portion thereof may be removed. For example, the edge portion (or the rim portion) of each of the third conductive layer CE1c made of titanium (Ti) and the fourth conductive layer CE1d made of indium tin oxide (ITO) may not be etched. This may prevent the other conductive layers of the first electrode CE1 from being corroded by a tetraMethylammoniumhydroxide (TMAH) solution used in a mask process of the first electrode CE1.

According to the present disclosure, each of the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer such as indium tin oxide (ITO) or indium zinc oxide (IZO), which has good adhesion to the solder pattern SDP and has corrosion resistance and acid resistance. However, embodiments of the present disclosure are not limited thereto.

The first conductive layer CE1a, the second conductive layer CE1b, the third conductive layer CE1c, and the fourth conductive layer CE1d may be sequentially deposited and then patterned by performing a photolithography process and an etching process thereon. However, embodiments of the present disclosure are not limited thereto.

According to the present disclosure, each of the signal line TL, the contact electrode CCE, and the pad electrode PE which are disposed at the same layer as a layer of the first electrode CE1, may be composed of multiple layers of a conductive material. However, embodiments of the present disclosure are not limited thereto. For example, each of the signal line TL, the contact electrode CCE, and the pad electrode PE may be composed of a multi-layer structure of indium tin oxide (Indium Tin Oxide, ITO) layer/titanium (Ti) layer/aluminum (Al) layer/titanium (Ti) layer. However, embodiments of the present disclosure are not limited thereto.

According to the present disclosure, the solder pattern SDP may be disposed on the first electrode CE1 and in each of the plurality of sub-pixels. The solder pattern SDP may bond the light-emitting element ED to the first electrode CEL. The first electrode CE1 and the light-emitting element ED may be electrically connected to each other via eutectic bonding using the solder pattern SDP. However, embodiments of the present disclosure are not limited thereto. For example, when the solder pattern SDP is made of indium (In) and the anode electrode 134 of the light-emitting element ED is made of gold (Au), heat and pressure may be applied thereto in the transfer process of the light-emitting element ED to bond the solder pattern SDP and the anode electrode 134 to each other. Via the eutectic bonding, the light-emitting element ED may be bonded to the solder pattern SDP and the first electrode CE1 without a separate adhesive. For example, the solder pattern SDP may be made of indium (In), tin (Sn), or an alloy thereof. However, embodiments of the present disclosure are not limited thereto. For example, the solder pattern SDP may be embodied as a bonding pad, a bonding pad, etc. However, embodiments of the present disclosure are not limited thereto.

According to the present disclosure, a passivation layer 116 may be disposed on the plurality of signal lines TL, the plurality of first electrodes CE1, the plurality of contact electrodes CCE, and the third insulating layer 115c. For example, the passivation layer 116 may be disposed in the display area AA, the first non-display area NA1, and the second non-display area NA2. A portion of the passivation layer 116 disposed in the bending area BA may be removed. A portion of the passivation layer 116 covering the plurality of pad electrodes PE in the second non-display area NA2 may be removed. Since the passivation layer 116 is disposed to cover the remaining area except for the bending area BA, an area of the plurality of pad electrodes PE, and an area of the solder pattern SDP, penetration of moisture or impurities flowing into the light-emitting element ED may be reduced. For example, the passivation layer 116 may be formed as a single layer or multiple layers made of silicon oxide (SiOₓ) or silicon nitride (SiNₓ). However, embodiments of the present disclosure are not limited thereto. For example, the passivation layer 116 may be embodied as a protective layer, an insulating layer, etc. However, embodiments of the present disclosure are not limited thereto. For example, the passivation layer 116 may have a hole defined therein exposing the solder pattern SDP.

In each of the plurality of sub-pixels, the light-emitting element ED may be disposed on the solder pattern SDP. The first light-emitting element 130 may be disposed in the first sub-pixel SP1. The second light-emitting element 140 may be disposed in the second sub-pixel SP2. The third light-emitting element 150 may be disposed in the third sub-pixel SP3.

The light-emitting element ED may be formed on a silicon wafer using an Metal Organic Chemical Vapor Deposition (MOCVD) method, a Chemical Vapor Deposition (CVD) method, a Plasma-Enhanced Chemical Vapor Deposition (PECVD) method, a Molecular Beam Epitaxy (MBE) method, a Hydride Vapor Phase Epitaxy (HVPE) method, or sputtering method. However, embodiments of the present disclosure are not limited thereto.

Referring to FIG. 9, the first light-emitting element 130 may include an anode electrode 134, a first semiconductor layer 131, an active layer 132, a second semiconductor layer 133, a cathode electrode 135, and an encapsulation film 136. However, embodiments of the present disclosure are not limited thereto. For example, the encapsulation film 136 may not be included in the first light-emitting element 130.

The first semiconductor layer 131 may be disposed on the solder pattern SDP. The second semiconductor layer 133 may be disposed on the first semiconductor layer 131. For example, one of the first semiconductor layer 131 and the second semiconductor layer 133 may be made of a compound semiconductor such as a group III-V, a group II-VI, or the like, and may be doped with impurities (or dopants). For example, one of the first semiconductor layer 131 and the second semiconductor layer 133 may be a semiconductor layer doped with n-type impurities, and the other thereof may be a semiconductor layer doped with p-type impurities. However, embodiments of the present disclosure are not limited thereto. For example, at least one of the first semiconductor layer 131 and the second semiconductor layer 133 may be a layer in which n-type or p-type impurities are doped in a material such as gallium nitride (GaN), gallium phosphide (GaP), gallium arsenide (GaAsP), aluminum gallium indium phosphide (AlGaInP), indium aluminum phosphide (InAlP), aluminum gallium nitride (AlGaN), aluminum indium gallium nitride (AlInN), aluminum gallium arsenide (AlGaAs), or gallium arsenide (GaAs). However, embodiments of the present disclosure are not limited thereto. For example, the n-type impurity may include silicon (Si), germanium (Ge), selenium (Se), carbon (C), tellurium (Te), tin (Sn), etc. However, embodiments of the present disclosure are not limited thereto. For example, the p-type impurity may include magnesium (Mg), zinc (Zn), calcium (Ca), strontium (Sr), barium (Ba), beryllium (Be), etc. However, embodiments of the present disclosure are not limited thereto.

For example, each of the first semiconductor layer 131 and the second semiconductor layer 133 may be made of a nitride semiconductor including n-type impurities and a nitride semiconductor including p-type impurities. However, embodiments of the present disclosure are not limited thereto. For example, the first semiconductor layer 131 may be made of a nitride semiconductor including p-type impurities, and the second semiconductor layer 133 may be made of a nitride semiconductor including n-type impurities. However, embodiments of the present disclosure are not limited thereto.

The active layer 132 may be disposed between the first semiconductor layer 131 and the second semiconductor layer 133. The active layer 132 may receive holes and electrons from the first semiconductor layer 131 and the second semiconductor layer 133 to emit light. For example, the active layer 132 may be composed of one of a single well structure, a multiple well structure, a single quantum well structure, a multi-quantum well (MQW) structure, a quantum dot structure, and a quantum wire structure. However, embodiments of the present disclosure are not limited thereto. For example, the active layer 132 may be made of indium gallium nitride (InGaN) or gallium nitride (GaN). However, embodiments of the present disclosure are not limited thereto.

In another example, the active layer 132 may include a MQW (Multi Quantum Well) structure having a well layer and a barrier layer having a higher band gap than that of the well layer. For example, the active layer 132 may include InGaN as a material of the well layer and AlGaN as a material of the barrier layer. However, embodiments of the present disclosure are not limited thereto.

The anode electrode 134 may be disposed between the first semiconductor layer 131 and the solder pattern SDP. For example, the anode electrode 134 may electrically connect the first semiconductor layer 131 and the first electrode CE1 to each other. The anode voltage output from the pixel driving circuit PD may be applied to the first semiconductor layer 131 via the signal line TL, the first electrode CE1, and the anode electrode 134. For example, the anode electrode 134 may be made of a conductive material capable of eutectic bonding with the solder pattern SDP. However, embodiments of the present disclosure are not limited thereto. For example, the anode electrode 134 may be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof. However, embodiments of the present disclosure are not limited thereto.

The cathode electrode 135 may be disposed on the second semiconductor layer 133. For example, the cathode electrode 135 may electrically connect the second semiconductor layer 133 and the second electrode CE2 to each other. The cathode voltage output from the pixel driving circuit PD may be applied to the second semiconductor layer 133 via the contact electrode CCE, the second electrode CE2, and the cathode electrode 135. The cathode electrode 135 may be made of a transparent conductive material so that light emitted from the light-emitting element ED may be directed upwardly of the light-emitting element ED. However, embodiments of the present disclosure are not limited thereto. For example, the cathode electrode 135 may be made of a material such as Indium Tin Oxide (ITO), Indium Zinc Oxide (IZO), or Indium Gallium Zinc Oxide (IGZO). However, embodiments of the present disclosure are not limited thereto.

The encapsulation film 136 may be disposed on at least a portion of each of the first semiconductor layer 131, the active layer 132, the second semiconductor layer 133, the anode electrode 134, and the cathode electrode 135. For example, the encapsulation film 136 may surround at least a portion of each of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may be disposed on a side surface of the first semiconductor layer 131, a side surface of the active layer 132, and a side surface of the second semiconductor layer 133.

For example, the encapsulation film 136 may be disposed on at least a portion of each of the anode electrode 134 and the cathode electrode 135, for example, an edge portion (or one side surface) of the anode electrode 134 and an edge portion (or one side surface) of the cathode electrode 135. At least a portion of the anode electrode 134 may not be covered with the encapsulation film 136 such that the anode electrode 134 and the solder pattern SDP are connected to each other. For example, at least a portion of the cathode electrode 135 may not be covered with the encapsulation film 136 such that the cathode electrode 135 and the second electrode CE2 are connected to each other. For example, the encapsulation film 136 may be made of an insulating material such as silicon nitride (SiNₓ) or silicon oxide (SiOₓ). However, embodiments of the present disclosure are not limited thereto.

In another example, the encapsulation film 136 may have a structure in which a reflective material is dispersed in a resin layer. However, embodiments of the present disclosure are not limited thereto. For example, the encapsulation film 136 may be embodied as a reflector having various structures. However, embodiments of the present disclosure are not limited thereto. Light emitted from the active layer 132 may be reflected upwardly from the encapsulation film 136, thereby improving light extraction efficiency. For example, the encapsulation film 136 may be a reflective layer. However, embodiments of the present disclosure are not limited thereto.

According to the present disclosure, an example in which the light-emitting element ED has a vertical structure has been described. However, embodiments of the present disclosure are not limited thereto. For example, the light-emitting element ED may have a lateral structure or a flip chip structure.

Although the first light-emitting element 130 has been described with reference to FIG. 9, each of the second light-emitting element 140 and the third light-emitting element 150 may have substantially the same structure as that of the first light-emitting element 130. For example, the first semiconductor layer, the active layer, the second semiconductor layer, the anode electrode, the cathode electrode, and the encapsulation film of each of the second light-emitting element 140 and the third light-emitting element 150 may be substantially the same as the first semiconductor layer 131, the active layer 132, the second semiconductor layer 133, the anode electrode 134, the cathode electrode 135, and the encapsulation film 136 of the first light-emitting element 130, respectively.

According to the present disclosure, a first optical layer 117a surrounding the plurality of light-emitting elements ED may be disposed in the display area AA. For example, the first optical layer 117a may be disposed to cover the plurality of light-emitting elements ED and the bank BNK in the areas of the plurality of sub-pixels. For example, the first optical layer 117a may cover the bank BNK, a portion of the passivation layer 116, and an area between adjacent ones of the plurality of light-emitting elements ED. The first optical layer 117a may be disposed in or cover an area between adjacent ones of the plurality of light-emitting elements ED included and an area between adjacent ones of the plurality of banks BNK in one pixel PX. For example, the first optical layer 117a may extend in the first direction X and the first optical layers 117a may be spaced apart from each other in the second direction Y. For example, the first optical layer 117a may be disposed between the passivation layer 116 and the second electrode CE2 so as to surround the side of each of the light-emitting element ED and the bank BNK. However, embodiments of the present disclosure are not limited thereto. For example, the first optical layer 117a may act as a diffusion layer, a sidewall diffusion layer, etc. However, embodiments of the present disclosure are not limited thereto.

The first optical layer 117a may include an organic insulating material in which fine particles are dispersed. However, embodiments of the present disclosure are not limited thereto. For example, the first optical layer 117a may be made of siloxane in which fine metal particles such as titanium dioxide (TiO₂) particles are dispersed. However, embodiments of the present disclosure are not limited thereto. Light from the plurality of light-emitting elements ED may be scattered by the fine particles dispersed in the first optical layer 117a and then emitted out of the display device 1000. Accordingly, the first optical layer 117a may improve extraction efficiency of light emitted from the plurality of light-emitting elements ED.

For example, the first optical layer 117a may be disposed in each of the plurality of pixels PX, or may be commonly disposed in some pixels PX arranged in the same row. However, embodiments of the present disclosure are not limited thereto. For example, the first optical layer 117a may be disposed in each of the plurality of pixels PX, or the plurality of pixels PX may share one first optical layer 117a with each other. In another example, each of the plurality of sub-pixels SP may separately include the first optical layer 117a. However, embodiments of the present disclosure are not limited thereto.

According to the present disclosure, a second optical layer 117b may be disposed on the passivation layer 116 and in the display area AA. For example, the second optical layer 117b may be disposed to surround the first optical layer 117a. For example, the second optical layer 117b may be in contact with a side surface of the first optical layer 117a. For example, the second optical layer 117b may be disposed in an area between adjacent ones of the plurality of pixels PX. However, embodiments of the present disclosure are not limited thereto. For example, the second optical layer 117b may act as a diffusion layer, a diffusion layer window, a window diffusion layer, etc. However, embodiments of the present disclosure are not limited thereto.

The second optical layer 117b may be made of an organic insulating material. However, embodiments of the present disclosure are not limited thereto. The second optical layer 117b may be made of the same material as that of the first optical layer 117a. However, embodiments of the present disclosure are not limited thereto. For example, the first optical layer 117a may include fine particles, and the second optical layer 117b may not include fine particles. For example, the second optical layer 117b may be made of siloxane. However, embodiments of the present disclosure are not limited thereto.

For example, a thickness of the first optical layer 117a may be smaller than a thickness of the second optical layer 117b. However, embodiments of the present disclosure are not limited thereto. Accordingly, in a cross-sectional view of the device, an area in which the first optical layer 117a is disposed may include a concave portion recessed downwardly beyond an upper surface of the second optical layer 117b.

According to the present disclosure, the second electrode CE2 may be disposed on the first optical layer 117a and the second optical layer 117b. For example, the second electrode CE2 may be electrically connected to the plurality of contact electrodes CCE via a contact hole of the second optical layer 117b. For example, the second electrode CE2 may be disposed on the plurality of light-emitting elements ED. For example, the second electrode CE2 may include a transparent conductive oxide such as indium tin oxide (ITO) or indium zinc oxide (IZO). However, embodiments of the present disclosure are not limited thereto. For example, the second electrode CE2 may be disposed to be in contact with the cathode electrode 135. For example, the second electrode CE2 may overlap the first optical layer 117a. For example, the second electrode CE2 may cover an upper surface of the first optical layer 117a.

The second electrode CE2 may continuously extend in the first direction of the substrate 110. Accordingly, the plurality of pixels PX arranged in the first direction of the substrate 110 may be commonly connected to the second electrode CE2. For example, the second electrode CE2 may be commonly connected to the plurality of pixels PX.

According to the present disclosure, the second electrode CE2 may continuously extend across the first optical layer 117a, the second optical layer 117b, and the light-emitting element ED. An area in which the first optical layer 117a is disposed may include the concave portion recessed downwardly beyond the upper surface of the second optical layer 117b. Accordingly, since a first portion of the second electrode CE2 disposed on the first optical layer 117a is disposed along and on the concave portion, a vertical level of the first portion may be lower than a vertical level of a second portion of the second electrode CE2 disposed on the second optical layer 117b.

A third optical layer 117c may be disposed on the second electrode CE2. The third optical layer 117c may be disposed to overlap the plurality of light-emitting elements ED and the first optical layer 117a. Since the third optical layer 117c is disposed on the second electrode CE2 and the plurality of light-emitting elements ED, a mura that may occur in some of the plurality of light-emitting elements ED may be suppressed. For example, when the plurality of light-emitting elements ED are transferred onto the substrate 110 of the display device 100, an area in which spacings between adjacent ones of the plurality of light-emitting elements ED are not uniform may occur due to process variations or etc. When the spacings between adjacent ones of the plurality of light-emitting elements ED are non-uniform, respective light emission areas of the plurality of light-emitting elements ED may be non-uniformly arranged, and thus, the mura may be visually recognized by the user. Accordingly, since the third optical layer 117c configured to uniformly diffuse light is formed on top of the plurality of light-emitting elements ED, a phenomenon that the light emitted from some light-emitting elements ED is visible as the mura to the user may be suppressed. Accordingly, the light emitted from the plurality of light-emitting elements ED may be uniformly diffused by the third optical layer 117c and then be extracted out of the display device 1000, such that the luminance uniformity of the display device 1000 may be improved.

The third optical layer 117c may be made of an organic insulating material in which fine particles are dispersed. For example, the third optical layer 117c may be made of siloxane in which fine metal particles such as titanium dioxide (TiO₂) particles are dispersed. However, embodiments of the present disclosure are not limited thereto. For example, the third optical layer 117c may be made of the same material as that of the first optical layer 117a. However, embodiments of the present disclosure are not limited thereto. For example, the third optical layer 117c may act as a diffusion layer, an upper surface diffusion layer, etc. However, embodiments of the present disclosure are not limited thereto. A refractive index of the third optical layer 117c may range from 1.50 to 1.55. In an example, the refractive index of the third optical layer 117c may be 1.53.

According to the present disclosure, light from the plurality of light-emitting elements ED may be scattered by the fine particles dispersed in the third optical layer 117c and be emitted out of the display device 1000. The third optical layer 117c may evenly mix light beams respectively emitted from the plurality of light-emitting elements ED with each other to further improve luminance uniformity of the display device 1000. In addition, light extraction efficiency of the display device 1000 may be improved by the light being scattered from the plurality of fine particles, and accordingly, the display device 1000 may operate at a low power level.

A black matrix BM may be disposed on the second electrode CE2, the first optical layer 117a, the second optical layer 117b, and the third optical layer 117c and in the display area AA. For example, the black matrix BM may fill a contact hole of the second optical layer 117b. Since the black matrix BM is constructed to cover the display area AA, the black matrix may reduce color mixing between light beams from the plurality of sub-pixels and may prevent external light reflection. For example, since the black matrix BM is also disposed in the contact hole via which the second electrode CE2 and the contact electrode CCE are connected to each other, light leakage between adjacent ones of the plurality of sub-pixels may be prevented.

For example, the black matrix BM may be made of an opaque material. However, embodiments of the present disclosure are not limited thereto. For example, the black matrix BM may be made of an organic insulating material to which a black pigment or a black dye is added. However, embodiments of the present disclosure are not limited thereto.

A cover layer 118 may be disposed on the black matrix BM and in the display area AA. The cover layer 118 may protect the components under the cover layer 118. For example, the cover layer 118 may be made of an organic insulating material. However, embodiments of the present disclosure are not limited thereto. For example, the cover layer 118 may be made of a photoresist, polyimide (PI), or a photo acryl-based material. However, embodiments of the present disclosure are not limited thereto. For example, the cover layer 118 may be embodied as an overcoat layer, an insulating layer, etc. However, embodiments of the present disclosure are not limited thereto.

The polarizing layer 293 may be disposed on the cover layer 118 via a first adhesive layer 291. The cover member 155 may be disposed on the polarizing layer 293 via a second adhesive layer 295. For example, each of the first adhesive layer 291 and the second adhesive layer 295 may include an OCA (Optically clear adhesive), an OCR (Optically clear resin), a PSA (Pressure sensitive adhesive), etc. However, embodiments of the present disclosure are not limited thereto.

According to the present disclosure, the plurality of pad electrodes PE may be disposed on the third insulating layer 115c and in the second non-display area NA2. For example, at least a portion of each of the plurality of pad electrodes PE may not be covered with the passivation layer 116 so as to be exposed. For example, the plurality of pad electrodes PE may be electrically connected to the (2-4)-th connection line 122c via a contact hole of the third insulating layer 115d.

An adhesive layer ACF may be disposed on the plurality of pad electrodes PE. The adhesive layer ACF may be an adhesive layer in which conductive balls are dispersed in an insulating material. However, embodiments of the present disclosure are not limited thereto. When heat or pressure is applied to the adhesive layer ACF, the conductive balls may be electrically connected to each other in an area to which the heat or pressure has been applied such that the adhesive layer ACF may be conductive. The adhesive layer ACF may be disposed between the plurality of pad electrodes PE and the flexible circuit board (or flexible film) 157 to attach or bond the flexible circuit board (or flexible film) 157 to the plurality of pad electrodes PE. For example, the adhesive layer ACF may be embodied as an anisotropic conductive film (ACF). However, embodiments of the present disclosure are not limited thereto.

The flexible circuit board (or flexible film) 157 may be disposed on the adhesive layer ACF. The flexible circuit board (or flexible film) 157 may be electrically connected to the plurality of pad electrodes PE via the adhesive layer ACF. Accordingly, the signals output from the flexible circuit board (or flexible film) 157 and the printed circuit board may be transmitted to the pixel driving circuit PD of the display area AA via the plurality of pad electrodes PE, the (2-4)-th connection line 122d, the (2-3)-th connection line 122c, the (2-1)-th connection line 122b, and the (2-1)-th connection line 122a.

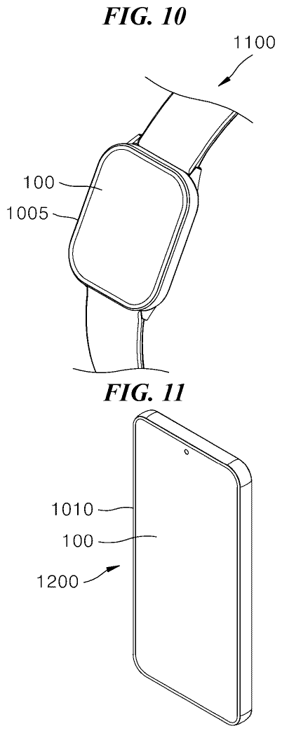

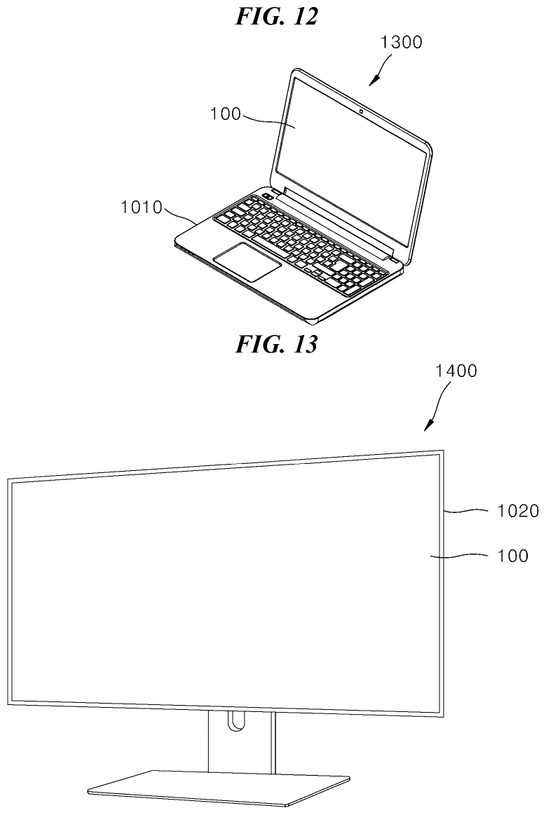

FIGS. 10 to 13 are diagrams illustrating an apparatus to which a display device according to embodiments of the present disclosure is applied.

Referring to FIGS. 10 to 13, a display device 1000 according to embodiments of the present disclosure may be included in various apparatus or electronic devices. For example, referring to FIGS. 10 to 13, various electronic devices may include a wearable device 1100, a mobile device 1200, a notebook computer 1300, and a monitor or TV 1400. However, embodiments of the present disclosure are not limited thereto.

Each of the wearable device 1100, the mobile device 1200, the notebook computer 1300, and the monitor or TV 1400 may include a casing 1005, 1010, 1015, or 1020 and the display device 1000 including the display panel 100 and according to embodiments of the present disclosure as described above with reference to FIGS. 1 to 9.

For example, the display device according to an embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), a MP3 player, a mobile medical device, a desktop PC, a laptop PC, a netbook computer, a workstation, a navigation system, a vehicle display device, a theater display device, a television, a wall paper device, a signage device, a game device, a notebook computer, a monitor, a camera, a camcorder, a home appliance, etc.

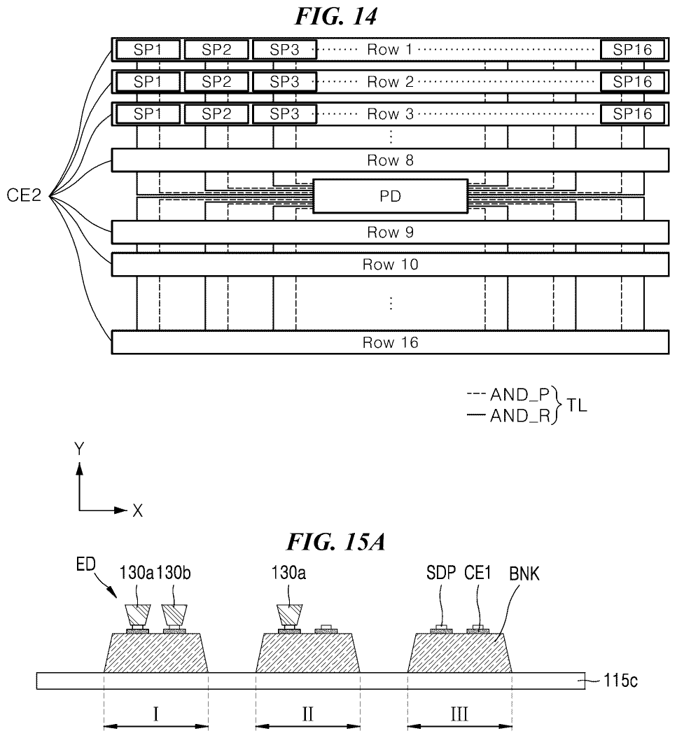

FIG. 14 is a plan view illustrating an area in which one pixel driving circuit among a plurality of pixel driving circuits is disposed.

Referring to FIGS. 3, 5, and 14 together, one pixel driving circuit PD may be electrically connected to the plurality of signal lines TL electrically connected to the plurality of sub-pixels. The plurality of sub-pixels may respectively include the plurality of light-emitting elements ED (see FIG. 3) arranged in the same column direction SP1, SP2, SP3, . . . , SP16 and the same row direction Row1, Row2, Row3, . . . , Row16.

The plurality of signal lines TL extending in the column direction may be disposed between adjacent ones of the plurality of sub-pixels. The plurality of signal lines TL may include a first line AND_P and a second line AND_R. The first line AND_P and the second line AND_R may be spaced apart from each other in the first direction X, which is a row direction. The first line AND_P and the second line AND_R may be electrically connected to the pair of subpixels SP, respectively. In each of the pair of sub-pixels, a light-emitting element ED may be disposed. Referring to FIG. 5 and FIG. 14 together, one of the pair of light-emitting elements ED may act as the main light-emitting element, and the other thereof may act as the redundant light-emitting element.

The first line AND_P may be a signal line disposed in an odd column. For example, referring to FIGS. 5 and 14 together, the first line AND_P may be each of the first signal line TL1, the third signal line TL3, and the fifth signal line TL5. The second line AND_R may be a signal line disposed in an even column. For example, the second line AND_R may be each of the second signal line TL2, the fourth signal line TL4, and the sixth signal line TL6. Each of the first line AND_P and the second line AND_R may be referred to as the signal line. Each of the plurality of second electrodes CE2 may extend in the row direction. The plurality of second electrodes CE2 may be spaced apart from each other in the second direction Y, which is a column direction.

The plurality of signal lines TL connected to the at least one pixel driving circuit PD may be radially connected thereto to connect each of a first sub-pixel SP1 disposed at a first position of the first row Row1 to a 16th sub-pixel SP16 opposite to the first sub-pixel SP1 and disposed at a 16th position thereof to the pixel driving circuit PD. For example, a shape in which the plurality of signal lines TL are connected to the at least one pixel driving circuit PD may be a rhombus shape or a shape of a letter ‘I’ in a plan view of the device.

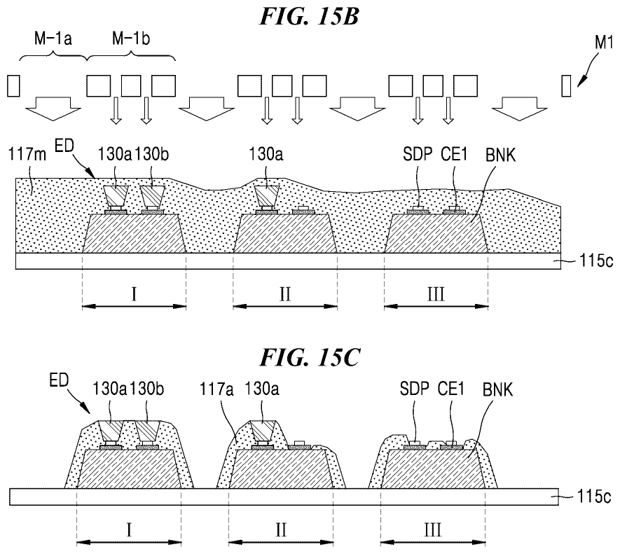

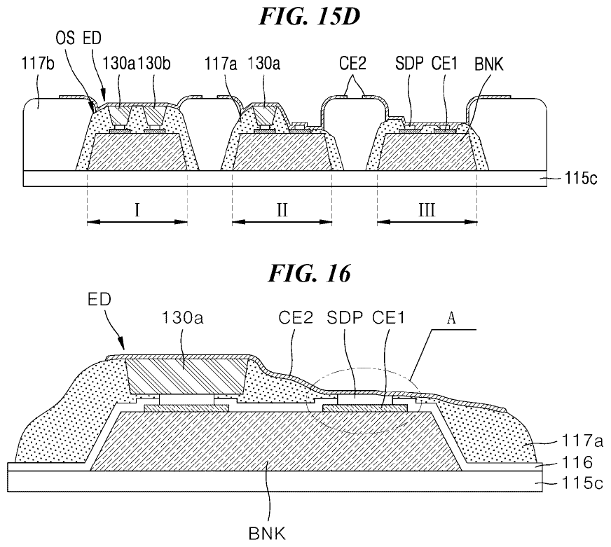

FIGS. 15A to 15D are diagrams illustrating a method for manufacturing a display device according to an embodiment of the present disclosure. FIG. 16 is an enlarged cross-sectional view of a portion of each of a plurality of sub-pixels of a display device according to an embodiment of the present disclosure. In FIGS. 15A to 16, the same reference numerals are allocated to the same components as the components as described in FIGS. 8 and 9, and thus, description thereof will be briefly made or omitted.

For convenience of illustration, FIGS. 15A to 15D illustrate only a process of transferring the first light-emitting element 130 to each of the plurality of first sub-pixels SP1. The process of transferring the light-emitting element onto each of the second sub-pixel SP2 and the third sub-pixel SP3 is substantially the same as the process of transferring the light-emitting element onto the first sub-pixel SPL. In addition, for convenience of illustration, the plurality of structures disposed under the bank BNK are not illustrated, but only the third insulating layer 115c in contact with a lower surface of the bank BNK is illustrated.

Referring to FIG. 15A, the bank BNK may be disposed on the third insulating layer 115c and in the display area. The first electrode CE1 and the solder pattern SDP may be disposed on the bank BNK. A transfer process of bonding each of the plurality of light-emitting elements ED onto each of the first electrodes CE1 is performed. For example, in the first sub-pixel SP1, the plurality of light-emitting elements ED may include the (1-1)-th light-emitting element 130a as the main light-emitting element, and the (1-2)-th light-emitting element 130b as the redundant light-emitting element.

The display area to which the plurality of light-emitting elements ED are transferred may include a first area I, a second area II, and a third area III. For example, the first area I may be an area to which both the (1-1)-th light-emitting element 130a and the (1-2)-th light-emitting element 130b are transferred. The second area II may be an area to which only one of the (1-1)-th light-emitting element 130a or the (1-2)-th light-emitting element 130b is transferred. The third area III may be an area to which neither the (1-1)-th light-emitting element 130a nor the (1-2)-th light-emitting element 130b is transferred.

Referring to FIG. 15B, a first optical material layer 117m is applied on the substrate. The first optical material layer 117m may be formed to have a thickness so as to cover the upper surfaces of the plurality of light-emitting elements ED. The first optical material layer 117m may include an organic insulating material in which fine metal particles are dispersed. For example, the fine metal particles may include titanium dioxide (TiO₂) particles. The organic insulating material may include siloxane.

A first exposure process is performed on the substrate using a first mask M1. The first mask M1 may be a half-tone mask. The half-tone mask may include a full-tone area M-1a, a half-tone area M-1b, and a light blocking area BA. As indicated by an arrow, a relatively larger amount of light than an amount of light irradiated to an area of the first optical material layer 117m corresponding to the half-tone area M-1b may be irradiated to an area of the first optical material layer 117m corresponding to the full-tone area M-1a. For example, the half-tone area M-1b may have a light transmittance of 10% compared with the full-tone area M-1a. In addition, the light blocking area BA may be an area in which light is blocked.

Referring to FIG. 15C, a developing process is performed on the light-exposed first optical material layer 117m to form the first optical layer 117a. An entirety of the area of the first optical material layer 117m corresponding to the full-tone area M-1a may be removed. The area corresponding to the half-tone area M-1b of the first optical material layer 117m may be irradiated with the relatively smaller amount of light than the amount of light irradiated to the full-tone area M-1a, so that an amount by which the first optical material layer 117a is removed may be adjusted.

The developing process may be performed using an upper surface of the light-emitting element LD as a target position. For example, the first optical material layer 117m may be removed until the upper surface of the light-emitting element LD is exposed and then may stop being removed when the upper surface of the light-emitting element LD is exposed. However, the first optical material layer 117m may be additionally removed at a position where at least one of the light-emitting elements LD is not transferred or all of the light-emitting elements LD are not transferred. Accordingly, the solder pattern SDP or the first electrode CE1 may be exposed.

For example, in the first area I, the first optical layer 117a may be disposed to surround the plurality of light-emitting elements 130a and 130b. In the first area I, the solder pattern SDP and the first electrode CE1 may be covered with the first optical layer 117a. For example, in the second area II, the first optical layer 117a may be disposed to surround the (1-1)-th light-emitting element 130a. In a portion of the second area II to which the light-emitting element is not transferred, the amount by which the first optical material layer 117a is removed increases, such that the solder pattern SDP or the first electrode CE1 may not be covered with the first optical layer 117m so as to be exposed. For example, the third area III is an area in which both the (1-1)-th light-emitting element 130a and the (1-2)-th light-emitting element 130b are not transferred. Thus, in the third area, the amount by which the first optical material layer 117m is removed increases, such that the solder pattern SDP or the first electrode CE1 may be exposed.

Referring to FIG. 15D, the second optical layer 117b may be disposed on an outer side OS of the first optical layer 117a. The second optical layer 117b may be disposed to surround the first optical layer 117a. The second optical layer 117b may be in contact with a side surface of the first optical layer 117a. The second electrode CE2 may be disposed on the first optical layer 117a, the second optical layer 117b, and the plurality of light-emitting elements ED.

However, the solder pattern SDP or the first electrode CE1 may contact the second electrode CE2, thereby causing a short circuit defect.

Referring to FIG. 16, the solder pattern SDP that is not covered with the first optical layer 117a may be exposed in an area ‘A’ to which the light-emitting element ED is not transferred. When the second electrode CE2 is disposed in the area A, the second electrode CE2 is disposed on the exposed solder pattern SDP, and thus a short circuit may occur between the second electrode CE2 and the first electrode CE1 to form a dark pixel on the display area.

Accordingly, another embodiment of the present disclosure may include a configuration capable of improving the reliability of the display device by preventing the dark pixel from occurring due to the short circuit between the second electrode CE2 and the first electrode CE1.

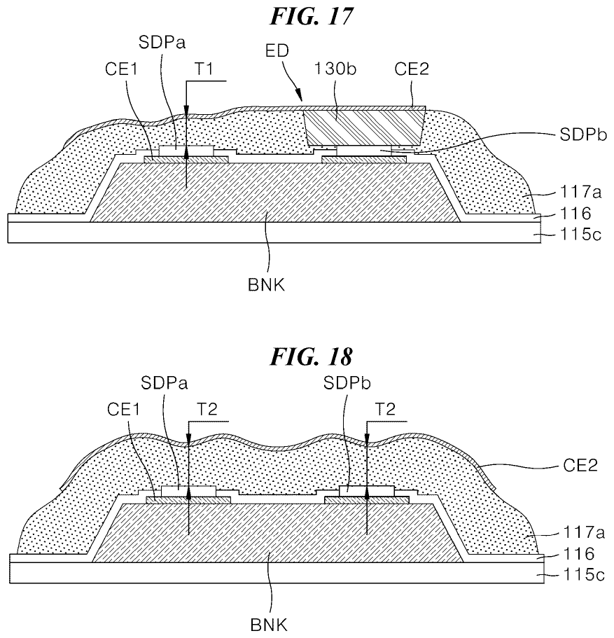

FIGS. 17 and 18 are enlarged cross-sectional views of one sub-pixel of a display device according to another embodiment of the present disclosure.

For convenience of description, FIGS. 17 and 18 are free of the second optical layer 117b but illustrate only the first optical layer 117a.

Referring to FIG. 17, the bank BNK may be disposed on the third insulating layer 115c. The first electrode CE1 and a solder pattern SDPa and SDPb may be disposed on the bank BNK. The solder pattern SDPa and SDPb may include a first solder pattern SDPa and a second solder pattern SDPb. The light-emitting element ED may be bonded on the solder pattern SDPa and SDPb. Only one of the (1-1)-th light-emitting element 130a and the (1-2)-th light-emitting element 130b may be transferred. For example, only the (1-2)-th light-emitting element 130b may be transferred onto the second solder pattern SDPb. The (1-1)-th light-emitting element 130a may not be transferred during the transfer process, so that the first solder pattern SDPa may be exposed.

The first optical layer 117a may be disposed on the (1-2)-th light-emitting element 130b. The first optical layer 117a may be disposed to be in contact with a side surface of the (1-2)-th light-emitting element 130b. The first optical layer 117a may be disposed on the first solder pattern SDPa. The first optical layer 117a may have a thickness sized such that the first solder pattern SDPa is not exposed. For example, a portion of the first optical layer 117a covering the first solder pattern SDPa may have a first thickness T1 from an upper surface of the first solder pattern SDPa. For example, the first thickness T1 of the portion of the first optical layer 117a covering the first solder pattern SDPa may be smaller than or equal to a thickness of a portion of the first optical layer 117a surrounding the sidewall of the (1-2)-th light-emitting element 130b. For example, the first thickness T1 of the portion of the first optical layer 117a may be at least 1 μm.

The second electrode CE2 may be disposed on the first optical layer 117a and the (1-2)-th light-emitting element 130b. The second electrode CE2 may be disposed on the first optical layer 117a covering the upper surface of the first solder pattern SDPa.

For example, the first optical layer 117a may include a first portion surrounding the sidewall of the (1-2)-th light-emitting element 130b and a second portion disposed on the first solder pattern SDPa and the second electrode CE2. This may prevent the first solder pattern SDPa from contacting the second electrode CE2 and thus prevent the short-circuit therebetween.

FIG. 18 is different from FIG. 17 in that FIG. 18 shows an area in which any light-emitting element is not transferred onto the sub-pixel. Referring to FIG. 18, the bank BNK may be disposed on the third insulating layer 115c. The first electrode CE1, the first solder pattern SDPa, and the second solder pattern SDPb may be disposed on the bank BNK. The first optical layer 117a may be disposed on the first solder pattern SDPa and the second solder pattern SDPb. The first optical layer 117a may cover each of the first solder pattern SDPa and the second solder pattern SDPb so as to have a second thickness T2 from an upper surface of each of the first solder pattern SDPa and the second solder pattern SDPb. For example, the second thickness T2 may be at least 1 μm.

The second electrode CE2 may be disposed on the first optical layer 117a. The second electrode CE2 may be disposed on the first optical layer 117a covering both of the first solder pattern SDPa and the second solder pattern SDPb. This may prevent the first solder pattern SDPa and the second solder pattern SDPb from being in contact with the second electrode CE2 and thus may prevent the short-circuit between each of the first solder pattern SDPa and the second solder pattern SDPb and the second electrode CE2.

According to another embodiment of the present disclosure, disposing the first optical layer OPL1 having the thickness sized such that the upper surface of the solder pattern SP that is not bonded to the light-emitting element LD is not exposed, thereby preventing the solder pattern SP and the second electrode EL2 from coming into contact with each other and being electrically short-circuited with each other. Accordingly, a defective pixel may be prevented from occurring due to the dark pixel in the display area.

Hereinafter, a method of disposing the first optical layer on the solder pattern will be described with reference to the drawings.

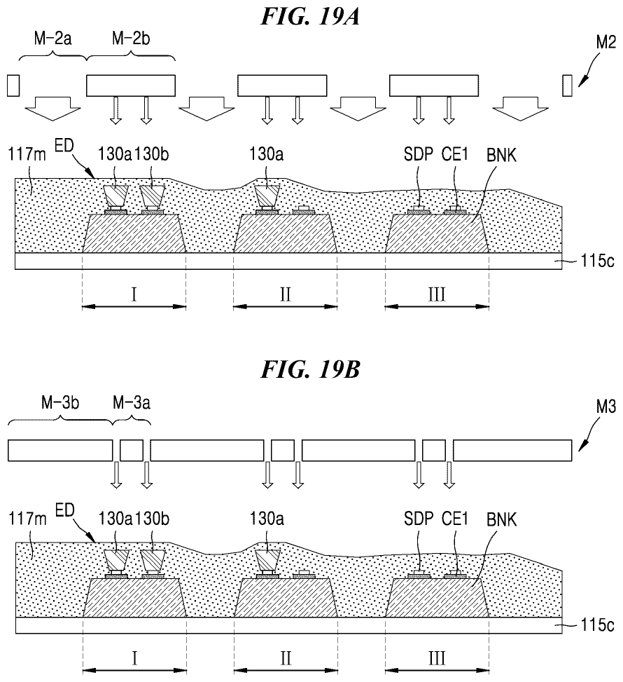

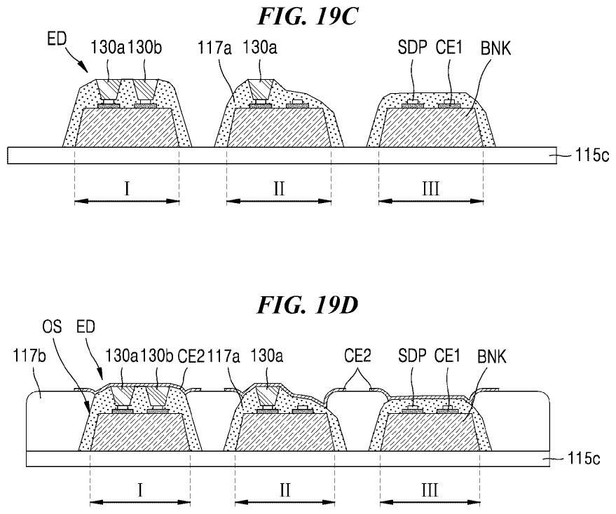

FIGS. 19A to 19D are diagrams illustrating a method for manufacturing a display device according to another embodiment of the present disclosure.

Referring to FIG. 19A, a plurality of banks BNK including banks to which a plurality of light-emitting elements ED have been transferred and a bank to which any light-emitting element ED is not transferred may be disposed on the third insulating layer 115c and in the display area. Each light-emitting element ED may be electrically connected to the first electrode CE1 via the solder pattern SDP. For example, in the first sub-pixel SP1, the plurality of light-emitting elements ED may include the (1-1)-th light-emitting element 130a as the main light-emitting element, and the (1-2)-th light-emitting element 130b as the redundant light-emitting element. The display area to which the plurality of light-emitting elements ED are transferred may include the first area I, the second area II, and the third area III.

Subsequently, the first optical material layer 117m is applied on the display area. The first optical material layer 117m may be applied at a rate of 1100 L/s. The first optical material layer 117m may be formed to have a thickness sized such that the upper surfaces of the plurality of light-emitting elements ED are not exposed. The first optical material layer 117m may include an organic insulating material in which fine metal particles are dispersed. For example, the fine metal particles may include titanium dioxide (TiO₂) particles. The organic insulating material may include siloxane.

Next, a first exposure process using a first mask M2 is performed on the substrate. The first mask M2 according to another embodiment of the present disclosure may be a full-tone mask. The first mask M2 may include a first full-tone area M-2a and a first light blocking area M-2b. The first light blocking area M-2b may correspond to the first area I, the second area II, and the third area III. The first full-tone area M-2a may have an opening in an area corresponding to an area in which the third insulating layer 115c and the first optical material layer 117m contact each other.

A portion of the first optical material layer 117m corresponding to or overlapping the first full-tone area M-2a may be irradiated with light as indicated by an arrow, while the first light blocking area M-2b may be an area in which light is blocked. The light irradiated in the first exposure process may be irradiated in an exposure amount range of 450 mJ to 500 mJ. After the first exposure process has been performed, the first mask M2 may be removed.

Referring to FIG. 19B, a second exposure process may be performed on the first optical layer 117m on which the first exposure process has been performed. The second exposure process may be performed to irradiate light onto a portion of the first optical material layer 117m covering the upper surfaces of the plurality of light-emitting elements ED.

The second exposure process may be performed using a second mask M3. The second mask M3 may include a second full-tone area M-3a and a second light blocking area M-3b. The second full-tone area M-3a may correspond to or overlap the first area I, the second area II, and the third area III. For example, an opening may be defined in a portion of the second full-tone area M-3a corresponding to or overlapping the portion of the first optical material layer 117m covering the upper surface of each of the plurality of light-emitting elements ED.

The second light blocking area M-3b may correspond to an area where the third insulating layer 115c and the first optical material layer 117m are in contact with each other. An amount of light irradiated in the second exposure process may be smaller than the light exposure amount irradiated in the first exposure process. For example, the light exposure amount in the second exposure process may be within a range in which a portion of the first optical material layer 117m remaining on the upper surface of each of the plurality of light-emitting elements ED may be removed. For example, the light irradiated in the second exposure process may be irradiated in an exposure amount range of 30 mJ to 50 mJ. After the second exposure process has been performed, the second mask M3 may be removed.

Referring to FIG. 19C, a developing process is performed on the light-exposed first optical material layer 117m to form the first optical layer 117a. Then, a process of curing the first optical layer 117a may be performed. An portion of the first optical material layer 117m corresponding to and overlapping the first full-tone area M-2a (see FIG. 19A) may be removed in the first exposure process. In addition, in the second exposure process, a portion thereof corresponding to and overlapping the second full-tone area M-3a (see FIG. 19A) may be removed. In this case, in the second exposure process, a portion of the first optical material layer corresponding to and overlapping the second light blocking area M-3b is not removed but remains.

The second exposure process may be performed in a range of an exposure amount relatively smaller than that of the first exposure process. For example, the light exposure amount in the second exposure process may be within a range in which the portion of the first optical material layer 117m remaining on the upper surface of each of the plurality of light-emitting elements ED may be removed. Accordingly, the first optical material layer 117m may be removed such that the first optical material layer 117m has different thicknesses in different areas thereof. For example, the first exposure process may be performed in a state in which an area in which the plurality of light-emitting elements LD are disposed is blocked from the light. The second exposure process may be performed in a relatively small exposure amount range in which the light is irradiated to the area in which the light-emitting elements LD are disposed. This may prevent the solder pattern SDP from being exposed in an area to which the light-emitting element is not transferred.

For example, in the first area I, the first optical material layer 117m may be removed to expose the upper surface of each of the (1-1)-th light-emitting element 130a and the (1-2)-th light-emitting element 130b. In the second area II, the first optical material layer 117m may be removed to expose the upper surface of the (1-1)-th light-emitting element 130a. In this case, the solder pattern SDP or the first electrode CE1 may not be exposed to the outside and may be covered with the first optical layer 117a in the remaining area to which the light-emitting element is not transferred. That is, in the third area III to which the light-emitting element is not transferred, the solder pattern SDP or the first electrode CE1 may not be exposed to the outside, and may be covered with the first optical layer 117a.

Referring to FIG. 19D, the second optical layer 117b may be disposed on an outer side OS of the first optical layer 117a. The second optical layer 117b may be disposed to surround the first optical layer 117a. The second optical layer 117b may be in contact with a side surface of the first optical layer 117a.

The second electrode CE2 may be disposed on the first optical layer 117a, the second optical layer 117b, and the plurality of light-emitting elements ED. The second electrode CE2 may be electrically connected to the cathode electrode of the light-emitting element ED to transmit a voltage to the light-emitting element ED.

As each of the light exposure amounts respectively irradiated in the first exposure process and the second exposure process are set to be different in different areas, the solder pattern SDP or the first electrode CE1 may be prevented from being exposed to the outside in each of the second area II and the third area III to which at least one light-emitting element ED is not transferred. Accordingly, the second electrode CE2 may be prevented from contacting the solder pattern SDP exposed to the outside, and thus, an electrical short may be prevented from occurring between the first electrode CE1 and the second electrode CE2. This may prevent a defective pixel from being generated due to a dark pixel as caused by the electrical short. Therefore, since the pixel PX may stably operate in the display area, the reliability of the display device may be improved.

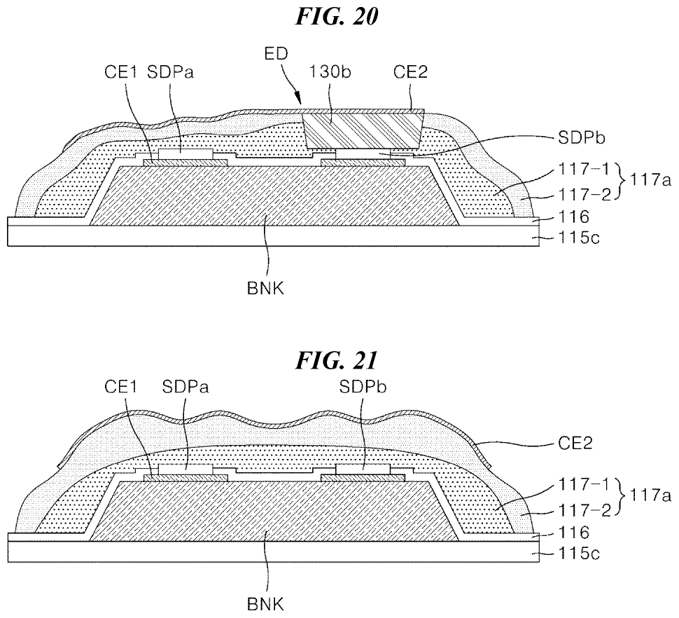

FIGS. 20 and 21 are enlarged cross-sectional views of one sub-pixel of a display device according to another embodiment of the present disclosure. For convenience of illustration, FIGS. 20 and 21 illustrate only the first optical layer 117a while being free of the second optical layer 117b.

Referring to FIG. 20, the bank BNK may be disposed on the third insulating layer 115c. The first electrode CE1 and the solder pattern SDPa and SDPb may be disposed on the bank BNK. The solder patterns SDPa and SDPb may include the first solder pattern SDPa and the second solder pattern SDPb. The light-emitting element ED may be bonded on the solder pattern SDPa and SDPb. Only one of the (1-1)-th light-emitting element 130a and the (1-2)-th light-emitting element 130b may be transferred. For example, only the (1-2)-th light-emitting element 130b may be transferred onto the second solder pattern SDPb. The (1-1)-th light-emitting element 130a may not be transferred during the transfer process, so that the first solder pattern SDPa may be exposed.

The first optical layer 117a may be disposed on the (1-2)-th light-emitting element 130b. The first optical layer 117a may be composed of a multilayer structure. For example, the first optical layer 117a may include a first layer 117-1 and a second layer 117-2 disposed on the first layer 117-1. In an embodiment of the present disclosure, a bilayer structure of the first layer 117-1 and the second layer 117-2 has been described. However, embodiments of the present disclosure are not limited thereto. For example, the first optical layer 117a may have a multilayer structure of three or more layers.

The first layer 117-1 and the second layer 117-2 of the first optical layer 117a may be made of different materials. For example, the first layer 117-1 as a lower layer of the first optical layer 117a may be made of an organic insulating material in which first fine metal particles are dispersed. The first fine particles may be dispersed in an amount ranging from 20 wt % to 30 wt % of a total weight of the organic insulating material of the first layer 117-1. For example, the first fine particle may have a first particle size. For example, the first particle size of the first fine particles may range from 400 nm to 1400 nm. For example, the first fine particle may be made of a polymer.

The second layer 117-2 disposed on the first layer 117-1 may be made of an organic insulating material in which second fine particles are dispersed. The second fine metal particles may be dispersed in an amount ranging from 30 wt % to 50 wt % of a total weight of the organic insulating material of the second layer 117-2. When the amount of the second fine metal particles dispersed in the second layer 117-2 is greater than 50 wt %, the light scattering characteristics may be deteriorated. For example, the second fine metal particle may have a second particle size. The second particle size may be relatively smaller than the first particle size of the first fine metal particle. For example, the second particle size may range from 200 nm to 280 nm. For example, the second fine metal particles dispersed in the second layer 117-2 may be made of a single component of titanium dioxide (TiO₂) or zinc oxide (ZnO). When the first fine metal particles dispersed in the second layer 117-2 are made of a mixture of the titanium dioxide (TiO₂) and zinc oxide (ZnO), dispersibility thereof in the second layer 117-2 may be deteriorated, thereby deteriorating the scattering effect of light. Accordingly, the second fine particles may be made of a single material of titanium dioxide (TiO₂) or zinc oxide (ZnO).

Since the first fine particles dispersed in the first layer 117-1 have the particle size relatively larger than that of the second fine particles dispersed in the second layer 117-2, light beams emitted toward the third insulating layer 115c among light beams emitted from the light-emitting element ED may be scattered by the first fine particles to allow a light path to be changed toward the second layer 117-2. Accordingly, the amount of light emitted to the outside may be increased by changing the path of light that may be emitted toward the third insulating layer 115c and thus may be extinguished. Accordingly, the light extraction efficiency may be improved to drive the display device at a low power level.

The fine particles having different particle sizes may be dispersed in the first layer 117-1 and the second layer 117-2 of the first optical layer 117a. When the second fine particles dispersed in the second layer 117-2 have a larger size than that of the first fine particles dispersed in the first layer 117-1, coating characteristics of the first optical layer 117a may be deteriorated. For example, the particles may protrude upwardly beyond a surface, and thus surface uniformity may be reduced. In addition, when the particle size is large, the particles may sink downwardly of the second layer 117-2 before the curing process is performed, and thus the scattering characteristics of light may be deteriorated. Accordingly, it is preferable that the second fine particles dispersed in the second layer 117-2 have a smaller size than the size of the first fine particles dispersed in the first layer 117-1.

The first layer 117-1 of the first optical layer 117a may be disposed to be in contact with the side surface of the (1-2)-th light-emitting element 130b. The first layer 117-1 may be disposed on the first solder pattern SDPa. The first layer 117-1 may have a thickness sized such that the first solder pattern SDPa is not exposed. For example, a portion of the first layer 117-1 covering the first solder pattern SDPa may have a thickness smaller than a thickness of a portion thereof surrounding the sidewall of the (1-2)-th light-emitting element 130b. Accordingly, an upper surface of the first layer 117-1 may be positioned at a vertical level lower than a vertical level of an upper surface of the (1-2)-th light-emitting element 130b. The first layer 117-1 may extend so as to cover the side surface of the bank BNK.

The second layer 117-2 of the first optical layer 117a may be disposed on the first layer 117-1. For example, the second layer 117-2 may be disposed along the surface of the first layer 117-1. The second layer 117-2 may be disposed to surround the (1-2)-th light-emitting element 113b. Accordingly, a stacked structure of the first layer 117-1 and the second layer 117-2 may be disposed in an area corresponding to and overlapping the first solder pattern SDPa. For example, the second layer 117-2 may have a thickness such that the upper surface thereof may have the same vertical level as a vertical level of the upper surface of the (1-2)-th light-emitting element 113b.

The second electrode CE2 may be disposed on the first optical layer 117a and the (1-2)-th light-emitting element 130b. The second electrode CE2 may be disposed on the second layer 117-2 of the first optical layer 117a. The first solder pattern SDPa may be spaced apart from the second electrode CE2 by the thickness of the first optical layer 117a. For example, the first optical layer 117a including the first layer 117-1 and the second layer 117-2 may have a total thickness of at least 1 μm. This may prevent the first solder pattern SDPa from contacting the second electrode CE2 and thus being short-circuited therewith.

Referring to FIG. 21, FIG. 21 has a difference from FIG. 20 in that an area in which any light-emitting element LD is not transferred onto the sub-pixel SP is shown in FIG. 21. Referring to FIG. 21, the first electrode CE1, the first solder pattern SDPa, and the second solder pattern SDPb may be disposed on the bank BNK. The first layer 117-1 of the first optical layer 117a may be disposed on the first solder pattern SDPa and the second solder pattern SDPb. The second layer 117-2 may be disposed on the first layer 117-1.

For example, the first layer 117-1 and the second layer 117-2 of the first optical layer 117a may be made of organic insulating materials in which different fine particles having different particle sizes are dispersed, respectively. For example, the first layer 117-1 may be made of an organic insulating material in which the first fine particles having a first particle size are dispersed. The second layer 117-2 may be made of an organic insulating material in which the second fine particles having a second particle size smaller than the first particle size are dispersed.

The second electrode CE2 may be disposed on the first optical layer 117a. The second electrode CE2 may be disposed on the second layer 117-2 of the first optical layer 117a covering the first solder pattern SDPa and the second solder pattern SDPb. Each of the first solder pattern SDPa and the second solder pattern SDPb may be spaced apart from the second electrode CE2 by the total thickness of the first layer 117-1 and the second layer 117-2 of the first optical layer 117a. For example, the first optical layer 117a including the first layer 117-1 and the second layer 117-2 may have the total thickness of at least 1 μm. This may prevent each of the first solder pattern SDPa and the second solder pattern SDPb from being in contact with the second electrode CE2 and thus being short-circuited therewith.

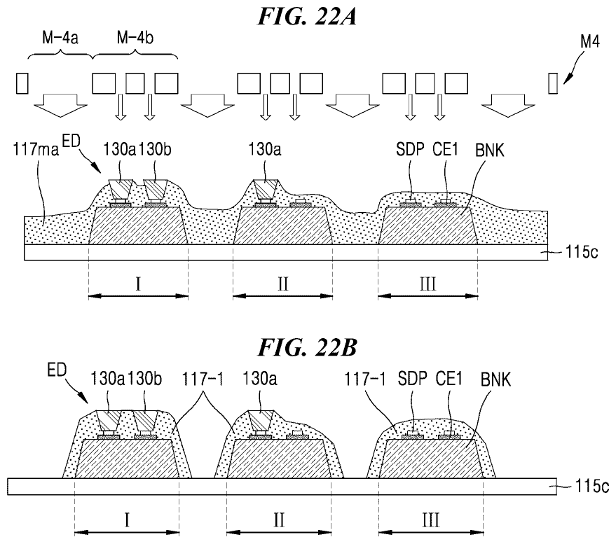

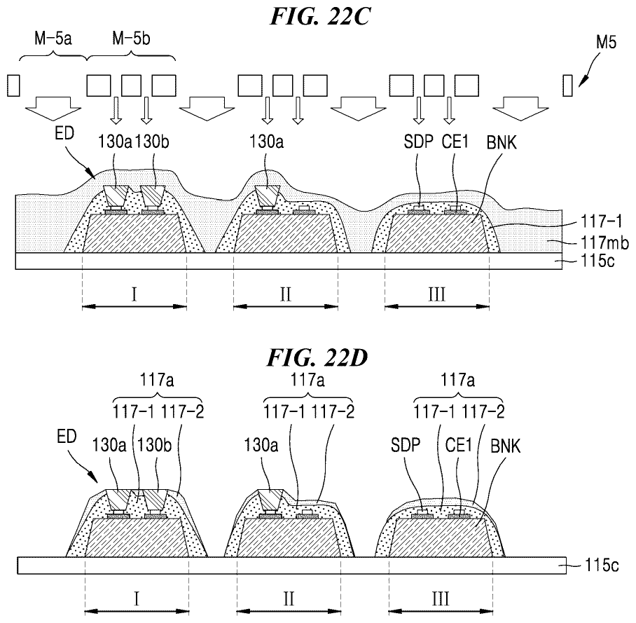

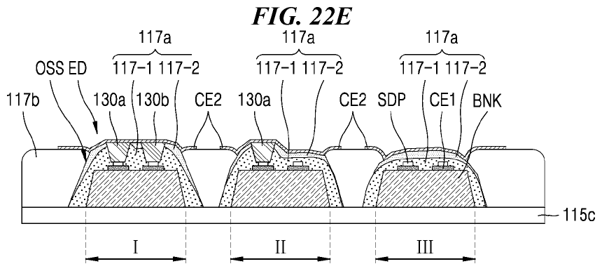

FIGS. 22A to 22E are diagrams illustrating a method for manufacturing a display device according to still another embodiment of the present disclosure. In FIGS. 22A to 22E, the same reference numerals are assigned to the same components as the components as described above with reference to FIGS. 8 and 9, and the description thereof will be briefly made or omitted.

Referring to FIG. 22A, a plurality of light-emitting elements ED may be transferred to the display area, and a first optical material layer 117ma may be applied thereto. The display area to which the plurality of light-emitting elements ED are transferred may include the first area I, the second area II, and the third area III. For example, in the first sub-pixel SP1, the plurality of light-emitting elements ED may include the (1-1)-th light-emitting element 130a as the main light-emitting element, and the (1-2)-th light-emitting element 130b as the redundant light-emitting element.

The first optical material layer 117ma may be applied at a rate of 550 L/s. The first optical material layer 117ma may be applied to have a thickness sized such that the solder pattern SDP is not exposed to the outside. For example, the first optical material layer 117ma may be applied to have the thickness sized such that a vertical level of the upper surface thereof is lower than a vertical level of the upper surface of each of the plurality of light-emitting elements ED. The first optical material layer 117ma may include an organic insulating material in which the first fine metal particles are dispersed. The first fine metal particle may have a first particle size. The first particle size may range from 400 nm to 1400 nm. The first fine metal particles may be dispersed in an amount ranging from 20 wt % to 30 wt % of a total weight of the organic insulating material of the first layer 117-1. For example, the first fine metal particle may include a polymer. The organic insulating material may include siloxane.

A first exposure process using a first mask M4 is performed on the substrate. The first mask M4 according to still another embodiment of the present disclosure may be a half-tone mask. The first mask M4 may include a first full-tone area M-4a, a first half-tone area M-4b, and a first light blocking area BA1. As indicated by an arrow, a relatively larger amount of light than an amount of light irradiated to a portion of the first optical material layer 117ma corresponding to the first half-tone area M-4b may be irradiated to a portion of the first optical material layer 117ma corresponding to the first full-tone area M-4a. In addition, the light blocking area BA may be an area in which light is blocked. The first full-tone area M-4a may have an opening defined therein in an area corresponding to an area in which the third insulating layer 115c and the first optical material layer 117ma contact each other.

The first half-tone area M-4b may have an opening in an area corresponding to or overlapping an area in which the light-emitting element ED is disposed.

The light exposure amount irradiated in the first exposure process may be relatively smaller in a range of 150 mJ to 200 mJ. After the first exposure process has been performed, the first mask M4 may be removed.

Referring to FIG. 22B, a developing process of removing the exposed portion on the first optical material layer 117ma on which the first exposure process has been performed may be performed to form the first layer 117-1 of the first optical layer. The first layer 117-1 of the first optical layer may surround the side of the light-emitting element ED and may have a thickness such that a vertical level of the upper surface thereof is lower than a vertical level of the upper surface of each of the plurality of light-emitting elements ED. The first layer 117-1 may extend so as to cover a side of the bank BNK. A curing process may not be performed on the first layer 117-1.

Referring to FIG. 22C, a second optical material layer 117mb may be applied on the first layer 117-1. The second optical material layer 117mb may be applied on the first layer 117-1 while filling a space between neighboring banks BNK. The second optical material layer 117mb may be applied at a rate of 550 L/s. The second optical material layer 117mb may include an organic insulating material in which the second fine metal particles are dispersed. For example, the second fine metal particle may have a second particle size. The second particle size may range from 200 nm to 280 nm. The second fine metal particles may be dispersed in an amount ranging from 30 wt % to 50 wt % of a total weight of the organic insulating material of the second layer 117-2. For example, the second fine metal particles may include titanium dioxide (TiO₂) particles or zinc oxide (ZnO) particles. The organic insulating material may include siloxane.

A second exposure process may be performed on the second optical material layer 117mb. The second exposure process may be performed to irradiate light onto the second optical material layer 117mb covering the upper surfaces of the plurality of light-emitting elements ED.

The second exposure process may be performed using a second mask M5. The second mask M5 may include a second full-tone area M-5a, a second half-tone area M-5b, and a light blocking area BA. The second half-tone area M-5b may correspond to the first area I, the second area II, and the third area III. For example, an opening may be defined in an area of the second half-tone area M-5b corresponding to a portion of the second optical material layer 117mb covering the upper surface of each of the plurality of light-emitting elements ED. The second full-tone area M-5a may have an opening in an area thereof corresponding to an area in which the third insulating layer 115c and the first layer 117-1 of the first optical layer OPL1 contact each other.

As indicated by an arrow, the light may be irradiated on the second mask M5. The second exposure process may be performed by irradiating light at the light exposure amount that does not exceed 200 mJ. After the second exposure process has been performed, the second mask M5 may be removed.

Referring to FIGS. 22C and 22D, a developing process is performed on the second optical material layer 117mb on which the second exposure process has been performed to form the second layer 117-2. Accordingly, the first optical layer 117a including the first layer 117-1 and the second layer 117-2 may be formed.

A portion of the second optical material layer 117mb corresponding to the second full-tone area M-5a may be removed in the second exposure process. The upper surface of each of the plurality of light-emitting elements ED may be exposed in an area corresponding to the second half-tone area M-5b. For example, the upper surface of each of the (1-1)-th light-emitting element 130a and the (1-2)-th light-emitting element 130b may be exposed in the first area I. In the second area II, the upper surface of the (1-1)-th light-emitting element 130a may be exposed. In addition, in a portion of the second area II to which the light-emitting element is not transferred, the solder pattern SDP or the first electrode CE1 is not exposed to the outside and is covered with the first optical layer 117a. In the third area III, the solder pattern SDP or the first electrode CE1 may be covered with the first optical layer 117a while the solder pattern SDP or the first electrode CE1 is not exposed to the outside.

Referring to FIG. 22E, the second optical layer 117b may be disposed on an outer side OSS of the first optical layer 117a. The second optical layer 117b may be disposed to surround the first optical layer 117a. The second optical layer 117b may be in contact with a side surface of the first optical layer 117a. The second electrode CE2 may be disposed on a portion of the first optical layer 117a, a portion of the second optical layer 117b, and the plurality of light-emitting elements ED. The second electrode CE2 may be disposed along the surface of the second layer 117-2 of the first optical layer 117a and may extend toward the second optical layer 117b. The solder pattern SDP and the second electrode CE2 may be spaced apart from each other by the total thickness of the first layer 117-1 and the second layer 117-2 of the first optical layer 117a. This may prevent the solder pattern SDP from contacting the second electrode CE2 and being electrically short-circuited therewith.

The display device according to various aspects and embodiments of the present disclosure may be described as follows.

A first aspect of the present disclosure provides a display device comprising: a substrate including a plurality of pixels; a plurality of pixel driving circuits respectively disposed on the plurality of pixels of the substrate; a plurality of banks disposed on each of the pixel driving circuits; a plurality of light-emitting elements respectively disposed on the plurality of banks; solder patterns disposed on the plurality of banks, wherein at least some of the solder patterns are respectively bonded to the plurality of light-emitting elements; an optical layer disposed on the plurality of banks; an electrode disposed on the plurality of light-emitting elements and the optical layer, wherein the optical layer is disposed between the solder pattern and the electrode.

In accordance with some embodiments of the first aspect of the present disclosure, the optical layer includes: a first optical layer surrounding each of the plurality of light-emitting elements; and a second optical layer disposed on an outer side of the first optical layer.

In accordance with some embodiments of the first aspect of the present disclosure, the solder patterns include: a first solder pattern bonded to each of the plurality of light-emitting elements; and a second solder pattern not bonded to any light-emitting element, wherein the optical layer is disposed between the second solder pattern and the electrode.

In accordance with some embodiments of the first aspect of the present disclosure, the optical layer includes: a first portion surrounding a sidewall of each of the plurality of light-emitting elements; and a second portion disposed between the second solder pattern and the electrode.

In accordance with some embodiments of the first aspect of the present disclosure, the second portion of the optical layer has a thickness of at least 1 μm.

In accordance with some embodiments of the first aspect of the present disclosure, the optical layer includes: a first optical layer surrounding each of the plurality of light-emitting elements; and a second optical layer disposed on an outer side of the first optical layer, wherein the first optical layer has a multi-layer structure.

In accordance with some embodiments of the first aspect of the present disclosure, the first optical layer having the multi-layer structure includes: a first layer; and a second layer disposed on top of the first layer.

In accordance with some embodiments of the first aspect of the present disclosure, the first layer and the second layer are made of different materials.

In accordance with some embodiments of the first aspect of the present disclosure, a vertical level of an upper surface of the first layer is lower than a vertical level of an upper surface of each of the plurality of light-emitting elements, wherein a vertical level of an upper surface of the second layer is equal to the vertical level of the upper surface of each of the plurality of light-emitting elements.

In accordance with some embodiments of the first aspect of the present disclosure, the first layer includes an organic insulating material in which first fine metal particles are dispersed, wherein the second layer includes an organic insulating material in which second fine metal particles are dispersed, wherein the first fine metal particle and the second fine metal particle are made of different materials from each other.

In accordance with some embodiments of the first aspect of the present disclosure, the first fine metal particle has a first particle size, and the second fine metal particle has a second particle size smaller than the first particle size.

In accordance with some embodiments of the first aspect of the present disclosure, the first fine metal particle includes a polymer.

In accordance with some embodiments of the first aspect of the present disclosure, the second fine metal particle includes a single component of titanium dioxide (TiO2) or zinc oxide (ZnO).

In accordance with some embodiments of each of the first and second aspects of the present disclosure, each of the plurality of light-emitting elements includes a micro light-emitting element having a vertical structure.

In accordance with some embodiments of each of the first and second aspects of the present disclosure, the electrode is disposed on one end of each of the light-emitting elements and is electrically connected to each of the plurality of pixel driving circuits, wherein the display device further comprises a further electrode facing the electrode and contacting the solder pattern so as to be connected to the other end of the light-emitting element via the solder pattern, wherein the further electrode is electrically connected to each of the plurality of pixel driving circuits.

In accordance with some embodiments of each of the first and second aspects of the present disclosure, each of the light-emitting elements is electrically connected to the further electrode via eutectic bonding of the solder pattern.

A second aspect of the present disclosure provides a display device comprising: a substrate including a plurality of pixels; a plurality of pixel driving circuits respectively disposed on the plurality of pixels of the substrate; a plurality of banks disposed on each of the pixel driving circuits; a plurality of light-emitting elements respectively disposed on the plurality of banks; solder patterns disposed on the plurality of banks, wherein at least some of the solder patterns are respectively bonded to the plurality of light-emitting elements; an optical layer disposed on the plurality of banks; and an electrode disposed on the optical layer and the plurality of light-emitting elements, wherein the optical layer is disposed between the solder pattern and the electrode, wherein the optical layer has a multi-layer structure.

In accordance with some embodiments of the second aspect of the present disclosure, the optical layer includes: a first optical layer surrounding each of the plurality of light-emitting elements; and a second optical layer disposed on an outer side of the first optical layer.

In accordance with some embodiments of the second aspect of the present disclosure, the first optical layer includes: a first layer; and a second layer disposed on top of the first layer, wherein the first layer and the second layer are made of different materials.

In accordance with some embodiments of the second aspect of the present disclosure, the first layer includes an organic insulating material in which first fine metal particles are dispersed, wherein the second layer includes an organic insulating material in which second fine metal particles are dispersed, wherein the first fine metal particle and the second fine metal particle are made of different materials from each other.

In accordance with some embodiments of the second aspect of the present disclosure, the first fine metal particle has a first particle size, and the second fine metal particle has a second particle size smaller than the first particle size.

In accordance with some embodiments of the second aspect of the present disclosure, the first particle size is in a range of 400 nm to 1400 nm, and the second particle size is in a range of 200 nm to 280 nm.

In accordance with some embodiments of the second aspect of the present disclosure, the first fine metal particles are contained in a content ranging from 20 wt % to 30 wt % of a total weight of the organic insulating material of the first layer, wherein the second fine metal particles are contained in a content ranging from 30 wt % to 50 wt % of a total weight of the organic insulating material of the second layer.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a plurality of pixels;
a plurality of pixel driving circuits respectively disposed on the plurality of pixels of the substrate;
a plurality of banks disposed on each of the pixel driving circuits;
a plurality of light-emitting elements respectively disposed on the plurality of banks;
solder patterns disposed on the plurality of banks, wherein at least some of the solder patterns are respectively bonded to the plurality of light-emitting elements;
an optical layer disposed on the plurality of banks;
an electrode disposed on the plurality of light-emitting elements and the optical layer,
wherein the optical layer is disposed between the solder pattern and the electrode.

2. The display device of claim 1, wherein the optical layer includes:
a first optical layer surrounding each of the plurality of light-emitting elements; and
a second optical layer disposed on an outer side of the first optical layer.

3. The display device of claim 1, wherein the solder patterns include:
a first solder pattern bonded to each of the plurality of light-emitting elements; and
a second solder pattern not bonded to any light-emitting element,
wherein the optical layer is disposed between the second solder pattern and the electrode.

4. The display device of claim 3, wherein the optical layer includes:
a first portion surrounding a sidewall of each of the plurality of light-emitting elements; and
a second portion disposed between the second solder pattern and the electrode.

5. The display device of claim 4, wherein the second portion of the optical layer has a thickness of at least 1 μm.

6. The display device of claim 1, wherein the optical layer includes:
a first optical layer surrounding each of the plurality of light-emitting elements; and
a second optical layer disposed on an outer side of the first optical layer,
wherein the first optical layer has a multi-layer structure.

7. The display device of claim 6, wherein the first optical layer having the multi-layer structure includes:
a first layer; and
a second layer disposed on top of the first layer.

8. The display device of claim 7, wherein the first layer and the second layer are made of different materials.

9. The display device of claim 7, wherein a vertical level of an upper surface of the first layer is lower than a vertical level of an upper surface of each of the plurality of light-emitting elements, and
wherein a vertical level of an upper surface of the second layer is equal to the vertical level of the upper surface of each of the plurality of light-emitting elements.

10. The display device of claim 8, wherein the first layer includes an organic insulating material in which first fine metal particles are dispersed,
wherein the second layer includes an organic insulating material in which second fine metal particles are dispersed, and
wherein the first fine metal particle and the second fine metal particle are made of different materials from each other.

11. The display device of claim 10, wherein the first fine metal particle has a first particle size, and the second fine metal particle has a second particle size smaller than the first particle size.

12. The display device of claim 10, wherein the first fine metal particle includes a polymer.

13. The display device of claim 10, wherein the second fine metal particle includes a single component of titanium dioxide (TiO₂) or zinc oxide (ZnO).

14. The display device of claim 1, wherein each of the plurality of light-emitting elements includes a micro light-emitting element having a vertical structure.

15. The display device of claim 1, wherein the electrode is disposed on one end of each of the light-emitting elements and is electrically connected to each of the plurality of pixel driving circuits,
wherein the display device further comprises a further electrode facing the electrode and contacting the solder pattern so as to be connected to the other end of the light-emitting element via the solder pattern, and
wherein the further electrode is electrically connected to each of the plurality of pixel driving circuits.

16. The display device of claim 15, wherein each of the light-emitting elements is electrically connected to the further electrode via eutectic bonding of the solder pattern.

17. A display device comprising:
a substrate including a plurality of pixels;
a pixel driving circuit disposed on each pixel of the plurality of pixels;
a bank disposed on the pixel driving circuit;
a plurality of light-emitting elements disposed on the bank;
solder patterns disposed on the bank, wherein at least one solder pattern of the solder patterns is bonded to a light-emitting element of the plurality of light-emitting elements;
an optical layer disposed on the bank; and
an electrode disposed on the optical layer and the plurality of light-emitting elements,
wherein the optical layer has a multi-layer structure.

18. The display device of claim 17, wherein the optical layer includes:
a first optical layer surrounding each of the plurality of light-emitting elements; and
a second optical layer disposed on an outer side of the first optical layer,
wherein the optical layer is disposed between the solder patterns and the electrode.

19. The display device of claim 18, wherein the first optical layer includes:
a first layer; and
a second layer disposed on top of the first layer,
wherein the first layer and the second layer are made of different materials.

20. The display device of claim 19, wherein the first layer includes an organic insulating material in which first fine metal particles are dispersed,
wherein the second layer includes an organic insulating material in which second fine metal particles are dispersed, and
wherein the first fine metal particle and the second fine metal particle are made of different materials from each other.

21. The display device of claim 20, wherein the first fine metal particle has a first particle size, and the second fine metal particle has a second particle size smaller than the first particle size.

22. The display device of claim 21, wherein the first particle size is in a range of 400 nm to 1400 nm, and the second particle size is in a range of 200 nm to 280 nm.

23. The display device of claim 21, wherein the first fine metal particles are contained in a content ranging from 20 wt % to 30 wt % of a total weight of the organic insulating material of the first layer, and
wherein the second fine metal particles are contained in a content ranging from 30 wt % to 50 wt % of a total weight of the organic insulating material of the second layer.
